(19) United States
(12) Patent Application Publication
(10) Pub. No.: US 2023/0163069 A1
(43) Pub. Date: May 25, 2023

(54) SEMICONDUCTOR DEVICE

(71) Applicant: ROHM CO., LTD., Kyoto-shi, Kyoto (JP)

(72) Inventors: Xiaopeng WU, Kyoto-shi, Kyoto (JP); Kazunori FUJI, Kyoto-shi, Kyoto (JP)

(21) Appl. No.: 17/915,975

(22) PCT Filed: Mar. 29, 2021
(86) PCT No.: PCT/JP2021/013300

§ 371 Date: Sep. 29, 2022

(30) Foreign Application Priority Data
Apr. 8, 2020 (JP) 2020-069751

(51) Int. Cl. H01L 23/528; H01L 25/07; H01L 23/367; H01L 23/498; H01L 29/20; H01L 29/778

(52) U.S. Cl. CPC H01L 23/528; H01L 25/072; H01L 23/3675; H01L 23/49844; H01L 29/2003; H01L 29/7786

(57) ABSTRACT

A semiconductor device includes a first semiconductor element, a second semiconductor element, an insulating layer, a sealing resin, a first external terminal, a second external terminal, a first connecting conductor and a second connecting conductor. Each of the semiconductor elements has an element front surface, an element back surface, and a plurality of front surface electrodes disposed on the element front surface. The insulating layer has an insulating layer back surface facing each of the element front surfaces and an insulating layer front surface facing away from the insulating layer back surface. The sealing resin has a resin front surface in contact with the insulating layer back surface and a resin back surface facing away from the resin front surface. The sealing resin covers a portion of each semiconductor element. Each external terminal is disposed between the first and the second semiconductor elements and exposed from the resin back surface. The first connecting conductor is disposed on the insulating layer and connects at least one of the front surface electrodes of the first semiconductor element to the first external terminal. The second connecting conductor is disposed on the insulating layer and connects at least one of the front surface electrodes of the second semiconductor to the second terminal.

### TECHNICAL FIELD

The present disclosure relates to a semiconductor device of a Fan-Out type.

### BACKGROUND ART

With recent miniaturization of electronic devices, size reduction of semiconductor devices for use in electronic devices is underway. Under such circumstances, a Fan-Out type semiconductor device has been developed. This type of semiconductor device has a semiconductor element with a plurality of electrodes, an insulating layer in contact with the semiconductor element, a plurality of connecting conductors disposed on the insulating layer and connected to the electrodes, and a sealing resin in contact with the insulating layer and covering a portion of the semiconductor element. The connecting conductors include portions located outside the semiconductor element as viewed in the thickness direction. The semiconductor device having such a configuration is advantageous in that it is adaptable to various wiring patterns of a wiring board on which the semiconductor device is to be mounted while achieving size reduction.

Patent Document 1 discloses an example of a Fan-Out type semiconductor device. The semiconductor device has a semiconductor element with a plurality of electrodes on its front surface, an insulating layer in contact with the front surface of the semiconductor element, a sealing resin in contact with the insulating layer and covering a portion of the semiconductor element, and a plurality of connecting conductors formed inside the insulating layer and including portions located outside the semiconductor element as viewed in the thickness direction. The semiconductor element is covered with the insulating layer and the sealing resin. The semiconductor device does not include an interposer or a printed wiring board and hence can be reduced in thickness.

A semiconductor device that constitutes a bridge circuit in which two switching elements are connected in series is demanded for use in converters or inverters. To realize such a semiconductor device as a Fan-Out type semiconductor device, two semiconductor elements, which are switching elements, are arranged side by side in a direction orthogonal to the thickness direction, and the source electrode of the first semiconductor element is electrically connected to the drain electrode of the second semiconductor element. The drain electrode of the first semiconductor element is electrically connected to an external terminal to which DC current is applied from outside. The source electrode of the second semiconductor element is electrically connected to an external terminal connected to ground. In such a semiconductor device, it is required to reduce the inductance of the current path inside the semiconductor device to reduce the surge voltage generated when the semiconductor elements are switched to the ON state.

### TECHNICAL REFERENCE

### Patent Document

Patent Document 1: JP-A-2019-29557

### SUMMARY OF THE INVENTION

### Problems to be Solved by the Invention

Under the above-noted circumstances, an object of the present disclosure is to provide a semiconductor device capable of reducing the inductance of the current path inside the semiconductor device.

### Means for Solving the Problems

A semiconductor device provided according to a first aspect of the present disclosure includes: a first semiconductor element and a second semiconductor element each having an element front surface and an element back surface facing away from each other in a thickness direction and a plurality of front surface electrodes disposed on the element front surface, the first semiconductor element and the second semiconductor element being arranged side by side in a first direction orthogonal to the thickness direction; an insulating layer having an insulating layer back surface covering and facing each of the element front surfaces and an insulating layer front surface facing away from the insulating layer back surface in the thickness direction; a sealing resin having a resin front surface in contact with the insulating layer back surface and a resin back surface facing away from the resin front surface in the thickness direction, the sealing resin covering a portion of each of the first semiconductor element and the second semiconductor element; a first external terminal and a second external terminal disposed between the first semiconductor element and the second semiconductor element and each exposed from the resin back surface; a first connecting conductor disposed on the insulating layer and electrically connecting at least one of the front surface electrodes of the first semiconductor element with the first external terminal; and a second connecting conductor disposed on the insulating layer and electrically connecting at least one of the front surface electrodes of the second semiconductor element with the second external terminal.

### Advantages of the Invention

The above arrangement makes it possible to reduce the area (magnetic field generation area) of the loop of the current path from the first external terminal to the second external terminal via the first connecting conductor, the semiconductor element, the semiconductor element and the second connecting conductor.

Other features and advantages of the present disclosure will become clearer from the detailed description given below with reference to the accompanying drawings.

### BRIEF DESCRIPTION OF THE DRAWINGS

FIG. 1 is a plan view of a semiconductor device according to a first embodiment of the present disclosure, seen through a third insulating layer 13;

FIG. 2 is a plan view of the semiconductor device of FIG. 1, seen further through a second insulating layer and a third connecting conductor;

FIG. 3 is a plan view of the semiconductor device of FIG. 1, seen further through a first insulating layer and all connecting conductors;

FIG. 4 is a bottom view of the semiconductor device of FIG. 1;

FIG. 5 is a sectional view taken along line V-V in FIG. 1;

FIG. 6 is a sectional view taken along line VI-VI in FIG. 1;

FIG. 7 is a partial enlarged view of FIG. 5;

FIG. 8 is a sectional view showing a step of an example of a method for manufacturing the semiconductor device of FIG. 1;

FIG. 9 is a sectional view showing a step of the example of a method for manufacturing the semiconductor device of FIG. 1;

FIG. 10 is a sectional view showing a step of the example of a method for manufacturing the semiconductor device of FIG. 1;

FIG. 11 is a partial enlarged view of FIG. 10;

FIG. 12 is a plan view showing a step of the example of a method for manufacturing the semiconductor device of FIG. 1;

FIG. 13 is a sectional view showing a step of the example of a method for manufacturing the semiconductor device of FIG. 1;

FIG. 14 is a partial enlarged view of FIG. 13;

FIG. 15 is a sectional view showing a step of the example of a method for manufacturing the semiconductor device of FIG. 1;

FIG. 16 is a sectional view showing a step of the example of a method for manufacturing the semiconductor device of FIG. 1;

FIG. 17 is a plan view showing a step of the example of a method for manufacturing the semiconductor device of FIG. 1;

FIG. 18 is a sectional view showing a step of the example of a method for manufacturing the semiconductor device of FIG. 1;

FIG. 19 is a sectional view showing a step of the example of a method for manufacturing the semiconductor device of FIG. 1;

FIG. 20 is a schematic diagram of the semiconductor device of FIG. 1, showing the flow of current;

FIG. 21 is a schematic diagram of the semiconductor device of FIG. 1, showing the flow of current;

FIG. 22 is a schematic diagram of the semiconductor device of FIG. 1, showing the flow of current;

FIG. 23 is a schematic diagram of the semiconductor device of FIG. 1, showing the flow of current;

FIG. 24 is a sectional view of a semiconductor device according to a second embodiment of the present disclosure;

FIG. 25 is a sectional view of a semiconductor device according to a third embodiment of the present disclosure;

FIG. 26 is a sectional view of a semiconductor device according to a fourth embodiment of the present disclosure;

FIG. 27 is a plan view of a semiconductor device according to a fifth embodiment of the present disclosure;

FIG. 28 is a sectional view of the semiconductor device of FIG. 27;

FIG. 29 is a plan view of a semiconductor device according to a sixth embodiment of the present disclosure; and

FIG. 30 is a sectional view taken along line XXX-XXX in FIG. 29.

### MODE FOR CARRYING OUT THE INVENTION

Preferred embodiments of the present disclosure are described below with reference to the accompanying drawings.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located an object B with another object interposed between the object A and the object B”. Also, the phrase “an object A overlaps with an object B as viewed in a certain direction” includes, unless otherwise specified, the object A overlaps with the entirety of the object B″ and “the object A overlaps with a portion of the object B”.

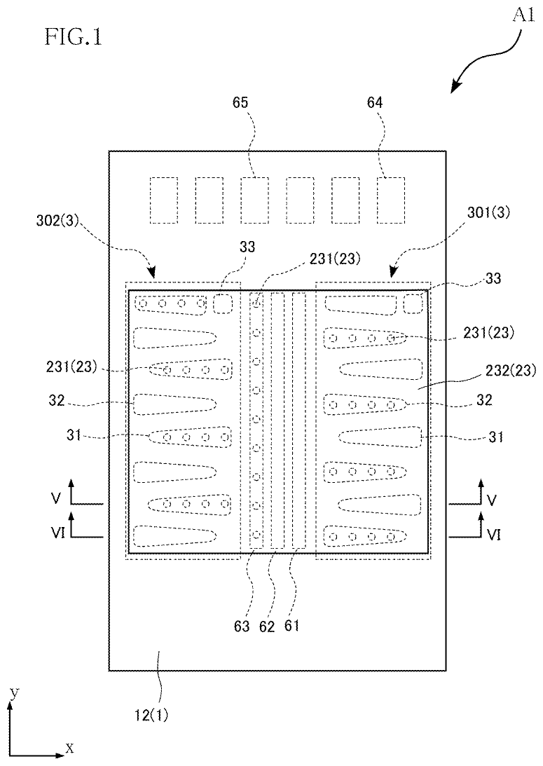

FIGS. 1-7 show an example of a semiconductor device according to the present disclosure. The semiconductor device A1 of the present embodiment includes an insulating layer 1, a plurality of connecting conductors 2, two semiconductor element 3, a sealing resin 4, two heat spreaders 5 and a plurality of external terminals 6. The insulating layer 1 includes a first insulating layer 11, a second insulating layer 12 and a third insulating layer 13. The connecting conductors 2 include a first connecting conductor 21, a second connecting conductor 22, a third connecting conductor 23, a connecting conductor 26 and a connecting conductor 27. The semiconductor device A1 is of a Fan-Out type to be surface-mounted on a wiring board.

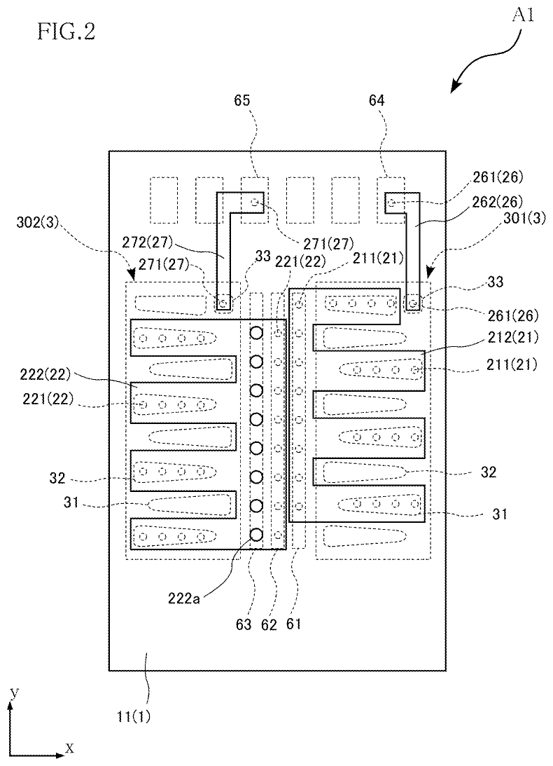

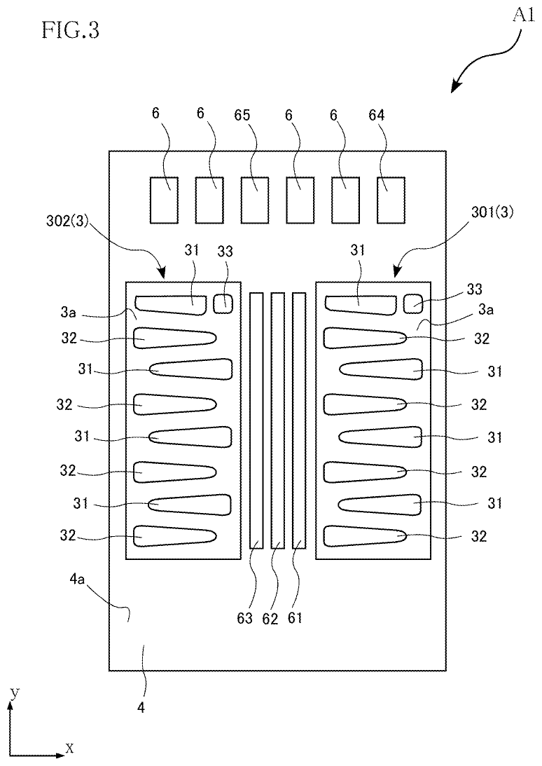

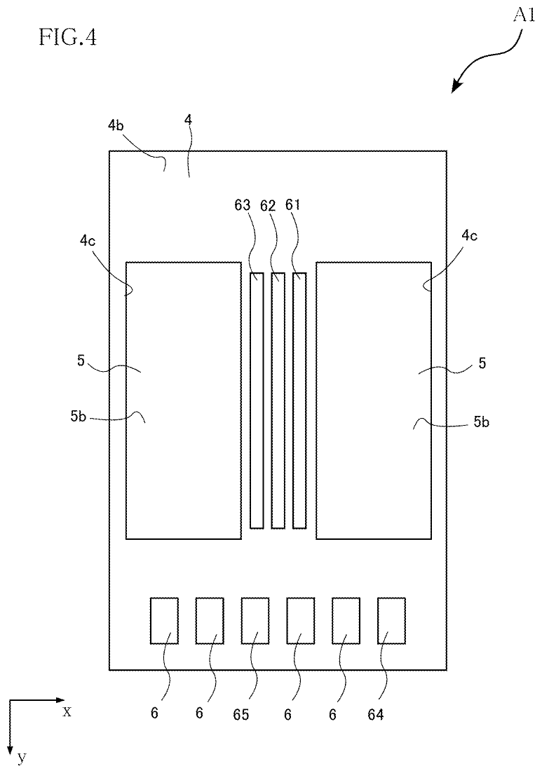

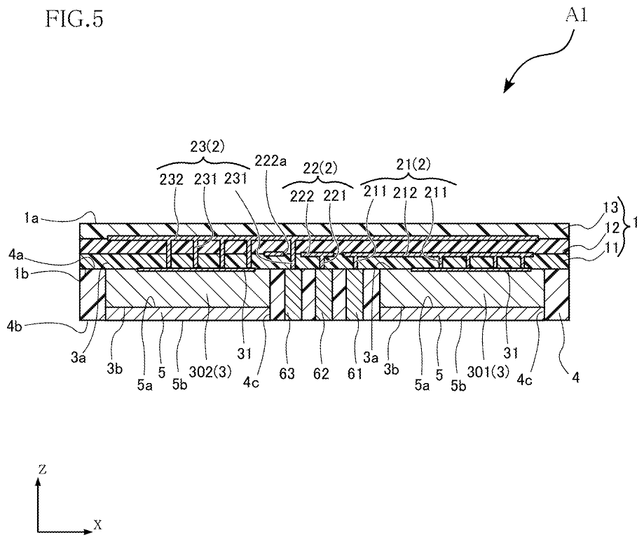

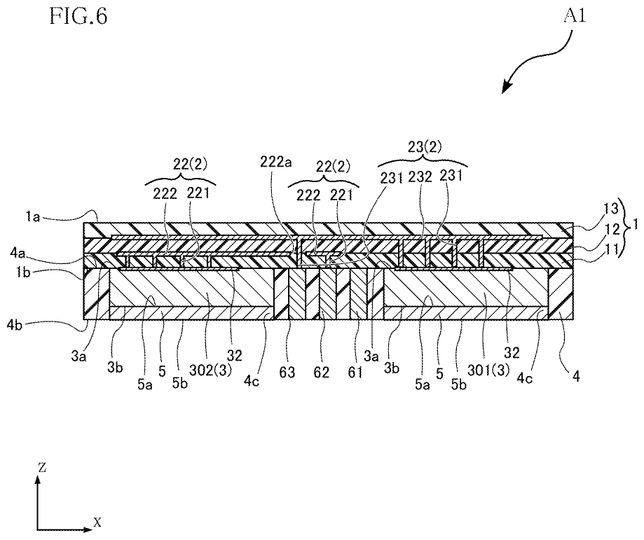

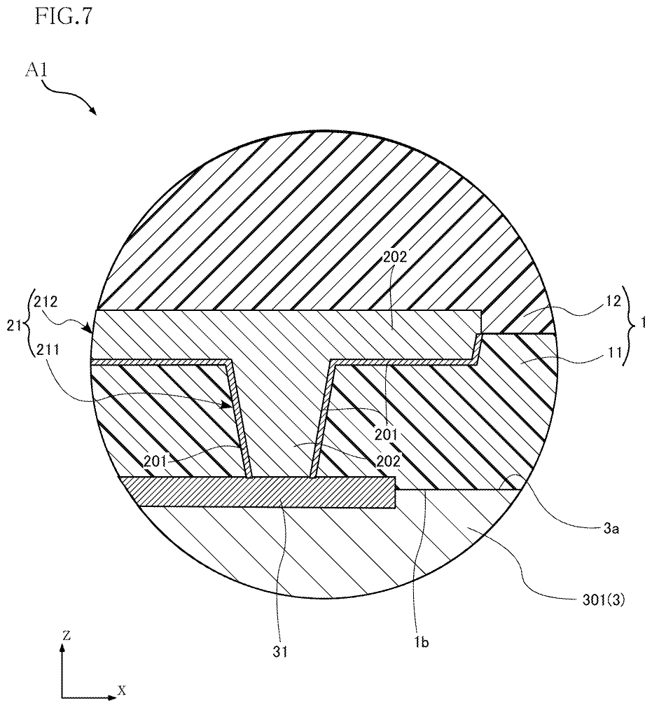

FIG. 1 is a plan view of a semiconductor device A1, seen through the third insulating layer 13. FIG. 2 is a plan view of a semiconductor device A1, seen further through the second insulating layer 12 and the third connecting conductor 23. FIG. 3 is a plan view of the semiconductor device A1, seen further through the first insulating layer 11 and all connecting conductors 2. FIG. 4 is a bottom view of the semiconductor device A1. FIG. 5 is a sectional view taken along line V-V in FIG. 1. FIG. 6 is a sectional view taken along line VI-VI in FIG. 1. FIG. 7 is a partial enlarged view of FIG. 5.

The semiconductor device A1 is in the form of a plate that is rectangular as viewed in the thickness direction (as viewed in plan). For convenience of description, the thickness direction (plan-view direction) of the semiconductor device A1 is referred to as z direction, the direction (horizontal direction in FIGS. 1-7) that is along one side of the semiconductor device A1 orthogonal to the z direction is referred to as x direction, and the direction (vertical direction in FIGS. 1-4) that is orthogonal to both of the z direction and the x direction is referred to as y direction. The z direction is one example of the “thickness direction”. The x direction is one example of the “first direction”. The size of the semiconductor device A1 is not limited.

The semiconductor element 3 is an element that performs electrical functions of the semiconductor device A1. In the present embodiment, the semiconductor device A1 has two semiconductor elements 3. When the two semiconductor element 3 are described separately, one is referred to as a semiconductor element 301 and the other as a semiconductor element 302. When the two are described collectively, they are simply referred to as semiconductor elements 3. In the present embodiment, the semiconductor element 3 is a high-electro-mobility transistor (HEMT) having an electron transit layer made of a nitride semiconductor, which may be gallium nitride (GaN) in the present embodiment).

Each of the semiconductor elements 3 is in the form of a plate that is rectangular as viewed in the thickness direction and has an element front surface 3a, an element back surface 3b, a plurality of input electrodes 31, a plurality of output electrodes 32 and a control electrode 33. The element front surface 3a and the element back surface 3b face away from each other in the z direction. As shown in FIG. 3, the input electrodes 31, the output electrodes 32 and the control electrode 33 are disposed on the element front surface 3a. The input electrodes 31 may be drain electrodes. The output electrodes 32 may be source electrodes. The control electrode 33 may be a gate electrode.

As shown in FIG. 3, as viewed in the z direction, the semiconductor element 301 and the semiconductor element 302 are disposed side by side in the x direction at approximately the center of the semiconductor device A1 in the y direction. In the present embodiment, the semiconductor element 301 is on the right side in FIG. 3 and the semiconductor element 302 is on the left side in FIG. 3. The type and position of the semiconductor elements 3 are not limited.

The heat spreaders 5 are in the form of a rectangular plate as viewed in the z direction and dissipate the heat generated by the semiconductor elements 3 to the wiring board on which the semiconductor device A1 is mounted. In the present embodiment, the semiconductor device A1 has two heat spreaders 5 to match the number of the semiconductor elements 3. One of the heat spreaders 5 is bonded to the semiconductor device 301, and the other of the heat spreaders 5 is bonded to the semiconductor device 302. Each heat spreader 5 is made of a material with high thermal conductivity and made of Cu in the present embodiment. The material for the heat spreaders 5 is not limited and may be other metals such as A1 or a ceramic material. Each heat spreader 5 has a spreader front surface 5a and a spreader back surface 5b. The spreader front surface 5a and the spreader back surface 5b face away from each other in the z direction. The heat spreaders 5 are bonded to the element back surfaces 3b of the semiconductor elements 3, with the spreader front surfaces 5a facing the semiconductor elements 3. In the present embodiment, the dimensions of the heat spreaders 5 in the x direction and y direction match the corresponding dimensions of the semiconductor elements 3, but the present disclosure is not limited to this. The spreader back surfaces 5b of the heat spreaders 5 are exposed from the sealing resin 4. In mounting the semiconductor device A1 on a wiring board, the spreader back surfaces 5b are bonded to the wiring board with a bonding material such as solder. Thus, the heat spreaders 5 dissipate the heat generated by the semiconductor elements 3 to the wiring board.

The sealing resin 4 covers a portion of each semiconductor element 3 and a portion of each heat spreader 5. The sealing resin 4 is made of a material containing, for example, black epoxy resin. The sealing resin 4 has a resin front surface 4a, a resin back surface 4b and resin openings 4c. The resin front surface 4a and the resin back surface 4b face away from each other in the z direction. In the present embodiment, the resin front surface 4a is flush with the element front surfaces 3a of the semiconductor elements 3 and in contact with the insulating layer 1. The sealing resin 4 may cover a portion of each element front surface 3a, as long as the input electrodes 31, the output electrodes 32 and the control electrode 33 are left exposed. The resin back surface 4b is a surface that faces a wiring board when the semiconductor device is mounted on the wiring board. The resin openings 4c are formed in the resin back surface 4b and overlap with the semiconductor elements 3 as viewed in the z direction. In the present embodiment, the spreader back surfaces 5b of the heat spreaders 5 are exposed through the resin openings 4c, and the resin back surface 4b and the spreader back surfaces 5b are flush with each other. A portion of each spreader back surface 5b may be covered with the sealing resin 4 as long as another portion of the spreader back surface is exposed from the sealing resin 4.

The external terminals 6 are made of a conductive material and made of Cu in the present embodiment. In the present embodiment, as shown in FIG. 3, the external terminals 6 include a first external terminal 61, a second external terminal 62, a third external terminal 63, a fourth external terminal 64 and a fifth external terminal 65.

Each of the first external terminal 61, the second external terminal 62 and the third external terminal 63 is in the form of a plate having a thickness in the x direction and rectangular as viewed in the thickness direction (as viewed in the x direction). The first external terminal 61, the second external terminal 62 and the third external terminal 63 are disposed between the semiconductor element 301 and the semiconductor element 302 at equal intervals, as viewed in the z direction. The first external terminal 61 is disposed adjacent to and spaced apart from the semiconductor device 301. The third external terminal 63 is disposed adjacent to and spaced apart from the semiconductor device 302. The second external terminal 62 is disposed between and spaced apart from the first external terminal 61 and the second external terminal 62. The first external terminal 61 is electrically connected to the input electrodes 31 of the semiconductor element 301. The second external terminal 62 is electrically connected to the output electrodes 32 of the semiconductor element 302. The third external terminal 63 is electrically connected to the output electrodes 32 of the semiconductor element 301 and the input electrodes 31 of the semiconductor element 302.

The external terminals 6 other than the first external terminal 61, the second external terminal 62 and the third external terminal 63 are each in the form of a rectangular parallelepiped and disposed at one end of the semiconductor device A1 in the y direction (see FIG. 3) and arranged side by side at equal intervals in the x direction. The fourth external terminal 64 is the external terminal 6 at the right end in FIG. 3 and is electrically connected to the control electrode 33 of the semiconductor element 301. The fifth external terminal 65 is the external terminal 6 at the fourth position from the right in FIG. 3 and is electrically connected to the control electrode 33 of the semiconductor element 302. The number, shape and arrangement of the external terminals 6 other than the first external terminal 61, the second external terminal 62 and the third external terminal 63 may vary.

Each external terminal 6 is mostly covered with the sealing resin 4. As shown in FIGS. 5 and 6, one surface of each external terminal 6 in the z direction of is exposed from the resin main surface 4a of the sealing resin 4. These surfaces are connected to the semiconductor elements 3 via connecting conductors 2. As shown in FIGS. 5 and 6, the other surface of each external terminal 6 in the z direction is exposed from the resin back surface 4b of the sealing resin 4. These surfaces are bonded to the conductors of a wiring board with a bonding material such as solder in mounting the semiconductor device A1 on the wiring board. Also, on these surfaces, metal layers may be laminated in the order of e.g. a nickel (Ni) layer, a palladium (Pd) layer and a gold (Au) layer or bumps made of a material containing tin (Sn) may be formed.

The first external terminal 61 is connected to the input electrodes 31 (drain electrodes) of the semiconductor element 301 via the first connecting conductor 21 (see FIGS. 2 and 5) and functions as a Vin terminal to which a DC voltage is applied from outside. The second external terminal 62 is connected to the output electrodes 32 (source electrodes) of the semiconductor element 302 via the second connecting conductor 22 (see FIGS. 2 and 6) and functions as a PGND terminal connected to ground. The third external terminal 63 is connected to the output electrodes 32 (source electrodes) of the semiconductor element 301 and the input electrodes 31 (drain electrodes) of the semiconductor element 302 via the third connecting conductor 23 (see FIGS. 1, 5 and 6) and functions as a SW terminal that outputs switching signals. The fourth external terminal 64 is connected to the control electrode 33 (gate electrode) of the semiconductor element 301 via the connecting conductor 26 (see FIG. 2) and functions as a signal terminal that inputs a drive signal to the semiconductor element 301. The fifth external terminal 65 is connected to the control electrode 33 (gate electrode) of the semiconductor element 302 via the connecting conductor 27 (see FIG. 2) and functions as a signal terminal that inputs a drive signal to the semiconductor element 302.

As shown in FIGS. 5 and 6, the insulating layer 1 is in contact with the element front surface 3a of each semiconductor element 3 and the resin front surface 4a of the sealing resin 4. The insulating layer 1 is made of a material containing a thermosetting synthetic resin and an additive containing a metallic element forming portions of the connecting conductors 2. The synthetic resin may be an epoxy resin or a polyimide resin, for example. The insulating layer 1 has an insulating layer front surface 1a and an insulating layer back surface 1b. The insulating layer front surface 1a and the insulating layer back surface 1b face away from each other in the z direction. The insulating layer back surface 1b is in contact with and faces the element front surface 3a of each semiconductor element 3 and the resin front surface 4a of the sealing resin 4, and covers the element front surface 3a of each semiconductor element 3 and the resin front surface 4a of the sealing resin 4. The insulating layer back surface 1b may not be in contact with the element front surface 3a of each semiconductor element 3.

The insulating layer 1 includes a first insulating layer 11, a second insulating layer 12 and a third insulating layer 13. As shown in FIGS. 5 and 6, the first insulating layer 11, the second insulating layer 12 and the third insulating layer 13 are laminated in this order on the sealing resin 4. The first insulating layer 11 is in contact with the element front surface 3a of each semiconductor element 3 and the resin front surface 4a of the sealing resin 4 and includes the insulating layer back surface 1b. The second insulating layer 12 is in contact with the first insulating layer 11. The third insulating layer 13 is in contact with the second insulating layer 12 and includes the insulating layer front surface 1a.

The connecting conductors 2 are conductors that connect the external terminals 6 and the semiconductor elements 3 and form a conduction path for supplying electric power to and inputting and outputting signals to and from the semiconductor elements 3. As shown in FIGS. 5 and 6, the connecting conductors 2 are disposed inside the insulating layer 1.

The first connecting conductor 21 has embedded parts 211 and a redistribution part 212. As shown in FIGS. 5 and 7, the embedded parts 211 are entirely embedded in the first insulating layer 11. As shown in FIG. 7, each embedded part 211 has a side surface inclined with respect to the z direction and is tapered such that the area of the cross section of the embedded part 211 orthogonal to the z direction becomes smaller as it approaches the insulating layer back surface 1b. As shown in FIGS. 5 and 7, the redistribution part 212 is disposed between the first insulating layer 11 and the second insulating layer 12. The redistribution part 212 is connected to the embedded parts 211. As shown in FIG. 2, as viewed in the z direction, the redistribution part 212 has a comb-teeth shape avoiding the output electrodes 32 of the semiconductor element 301. Such a shape allows the embedded parts 231 of the third connecting conductors 23, which will be described later, to be connected to the output electrodes 32. The redistribution part 212 may not have a comb-teeth shape but may be formed with through-holes for disposing the embedded parts 231 for connection to the output electrodes 32. As shown in FIG. 2, as viewed in the z direction, portions of the redistribution part 212 of the first connecting conductor 21 overlap with the semiconductor element 301, and portions of the redistribution part 212 are located outside the semiconductor element 301.

As shown in FIG. 7, each of the embedded parts 211 and the redistribution part 212 has a base layer 201 and a plating layer 202. The base layer 201 is formed of a metallic element contained in the additive that is contained in the first insulating layer 11. The base layer 201 is in contact with the first insulating layer 11. The plating layer 202 is made of a material containing copper (Cu), for example, and in contact with the base layer 201. The base layer 201 of the embedded part 211 is in contact with the first insulating layer 11. The plating layer 202 of the embedded part 211 is surrounded by the base layer 201 of the embedded part 211. The base layer 201 of the redistribution part 212 is in contact with the first insulating layer 11. The plating layer 202 of the redistribution part 212 covers the base layer 201 of the redistribution part 212 and is enclosed by the base layer 201 of the redistribution part 212 and the second insulating layer 12.

The second connecting conductor 22 has embedded parts 221 and a redistribution part 222. As shown in FIG. 6, the embedded parts 221 are entirely embedded in the first insulating layer 11. The shape of the embedded parts 221 is the same as that of the embedded parts 211. As shown in FIGS. 5 and 6, the redistribution part 222 is disposed between the first insulating layer 11 and the second insulating layer 12. The redistribution part 222 is connected to the embedded parts 221. As shown in FIG. 2, as viewed in the z direction, the redistribution part 222 has a comb-teeth shape avoiding the input electrodes 31 of the semiconductor element 302. Such a shape allows the embedded parts 231 of the third connecting conductor 23 to be connected to the input electrodes 31. The redistribution part 222 may not have a com-teeth shape but may be formed with through-holes for disposing the embedded parts 231 for connection to the input electrodes 31. As shown in FIGS. 2, 5 and 6, the redistribution part 222 has a plurality of through-holes 222a. Each through-hole 222a is a hole penetrating the redistribution part 222 in the z direction and disposed at a location overlapping with the third external terminal 63 as viewed in the z direction. In the through-holes 222a, the embedded parts 231 of the third connecting conductor 23, which will be described later, are disposed. As shown in FIG. 2, as viewed in the z direction, portions of the redistribution part 222 of the second connecting conductor 22 overlap with the semiconductor element 302, and portions of the redistribution part 222 are located outside the semiconductor element 302. As with the embedded parts 211 and the redistribution part 212, each of the embedded parts 221 and the redistribution part 222 has a base layer 201 and a plating layer 202.

The connecting conductor 26 has embedded parts 261 and a redistribution part 262. The embedded parts 261 are entirely embedded in the first insulating layer 11. The shape of the embedded parts 261 is the same as that of the embedded parts 211. The redistribution part 262 is disposed between the first insulating layer 11 and the second insulating layer 12. The redistribution part 262 is connected to the embedded parts 261. As shown in FIG. 2, a portion of the redistribution part 262 of the connecting conductor 26 overlaps with the semiconductor element 301, and a portion of the redistribution part 262 is located outside the semiconductor element 301. As with the embedded parts 211 and the redistribution part 212, each of the embedded parts 261 and the redistribution part 262 has a base layer 201 and a plating layer 202.

The connecting conductor 27 has embedded parts 271 and a redistribution part 272. The embedded parts 271 are entirely embedded in the first insulating layer 11. The shape of the embedded parts 271 is the same as that of the embedded parts 211. The redistribution part 272 is disposed between the first insulating layer 11 and the second insulating layer 12. The redistribution part 272 is connected to the embedded parts 271. As shown in FIG. 2, a portion of the redistribution part 272 of the connecting conductor 27 overlaps with the semiconductor element 302, and a portion of the redistribution part 272 is located outside the semiconductor element 302. As with the embedded parts 211 and the redistribution part 212, each of the embedded parts 271 and the redistribution part 272 has a base layer 201 and a plating layer 202.

The third connecting conductor 32 has embedded parts 231 and a redistribution part 232. As shown in FIGS. 5 and 6, the embedded parts 231 are entirely embedded through the first insulating layer 11 and the second insulating layer 12. The embedded parts 231 are arranged so as not to overlap with the redistribution part 212 or the redistribution part 222 as viewed in the z direction. The embedded parts 231 connected to the third external terminal 63 are disposed in the through-holes 222a of the redistribution part 222. The embedded parts 231 connected to the output electrodes 32 of the semiconductor element 301 are disposed between the comb teeth of the redistribution part 212. The embedded parts 231 connected to the input electrodes 31 of the semiconductor element 302 are disposed between the comb teeth of the redistribution part 222. The shape of the embedded parts 231 is the same as that of the embedded parts 211. As shown in FIGS. 5 and 6, the redistribution part 232 is disposed between the second insulating layer 12 and the third insulating layer 13. The redistribution part 232 is connected to the embedded parts 231. As shown in FIG. 1, the redistribution part 232 is rectangular as viewed in the z direction. The shape of the redistribution part 232 as viewed in the z direction is not limited, and may be any shape that overlaps with all of the embedded parts 231. As shown in FIG. 1, as viewed in the z direction, portions of the redistribution part 232 of the third connecting conductor 23 overlap with the semiconductor element 301 or the semiconductor element 302, and portions of the redistribution part 222 are located outside the semiconductor element 301 and the semiconductor element 302 (between the semiconductor element 301 and the semiconductor element 302 in the present embodiment). As with the embedded parts 211 and the redistribution part 212, each of the embedded parts 231 and the redistribution part 232 has a base layer 201 and a plating layer 202.

The semiconductor device A1 may include a redistribution part that overlaps with a semiconductor element 3 and has no part located outside the semiconductor element 3, or a redistribution part entirely located outside a semiconductor element 3.

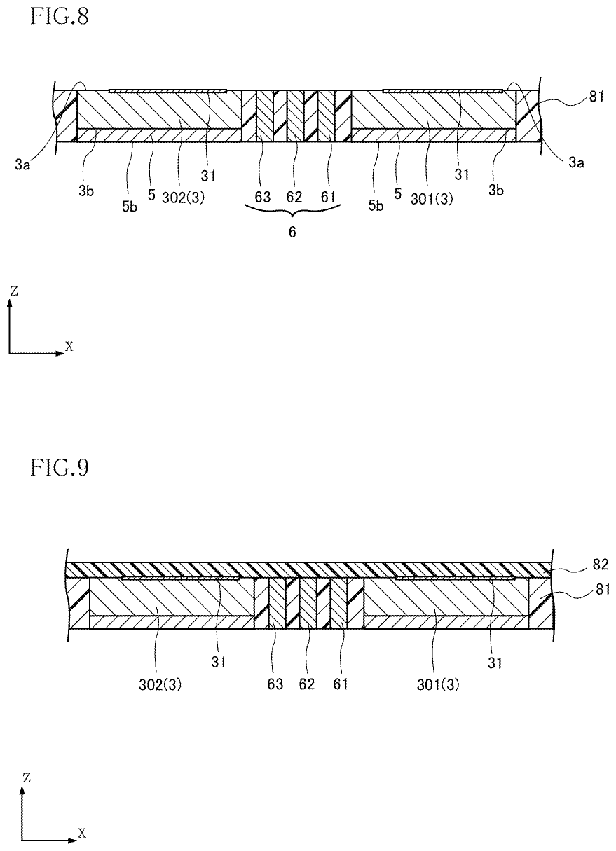

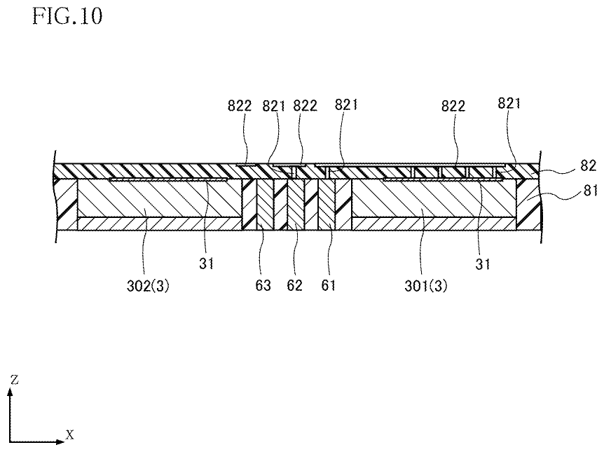

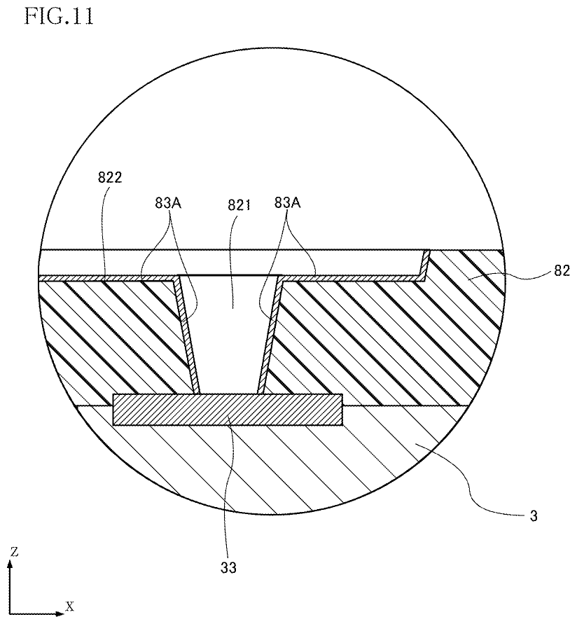

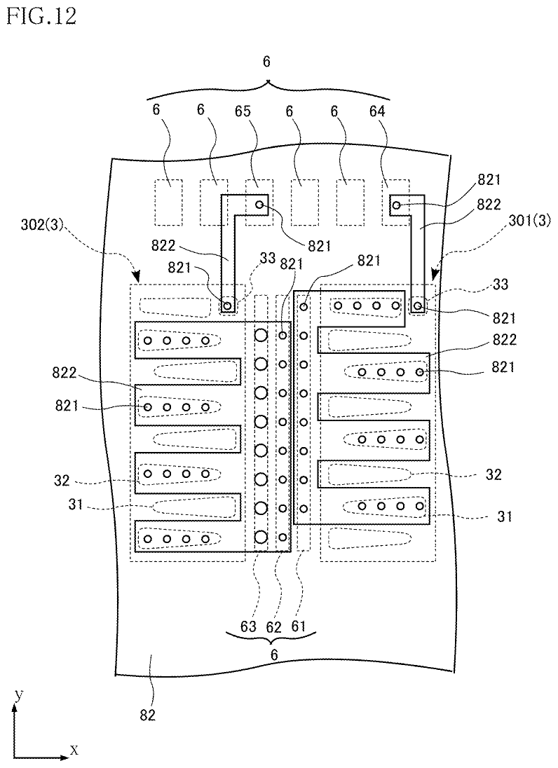

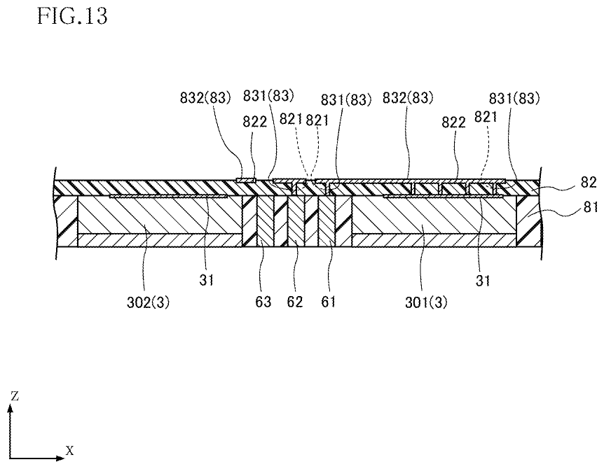

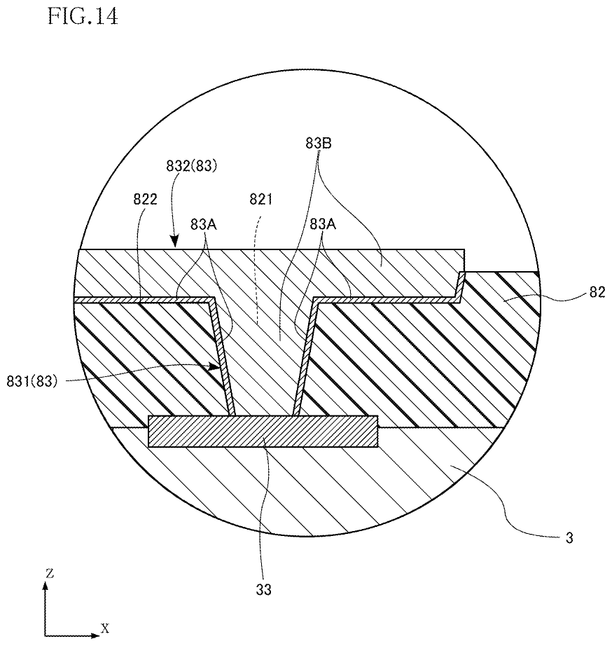

An example of a method for manufacturing the semiconductor device A1 is described below with reference to FIGS. 8-19. FIGS. 8-19 each show a step of an example of a method for manufacturing the semiconductor device A1. FIGS. 8-10, 13, 15, 16, 18 and 19 are sectional views corresponding to FIG. 5. FIG. 11 is a partial enlarged view of FIG. 10 and corresponds to FIG. 7. FIG. 12 is a plan view corresponding to FIG. 2. FIG. 14 is a partial enlarged view of FIG. 13 and corresponds to FIG. 7. FIG. 17 is a plan view corresponding to FIG. 1.

First, as shown in FIG. 8, the semiconductor elements 3 to which heat spreaders 5 are bonded and the external terminals 6 are embedded into the sealing resin 81. The sealing resin 81 is made of a material containing black epoxy resin. Each of the semiconductor elements 3 has input electrodes 31, output electrodes 32 and a control electrode 33 disposed on the element front surface 3a, and a heat spreader 5 bonded to the element back surface 3b. In this step, after the material for the sealing resin 81, the semiconductor elements 3 to which the heat spreaders 5 are bonded, and the external terminals 6 are placed in a mold, compression molding is performed. This step is performed such that the input electrodes 31, the output electrodes 32, the control electrodes 33 and the spreader back surfaces 5b of the heat spreader 5 are exposed from the sealing resin 81.

Next, as shown in FIG. 9, a first insulating layer 82 is formed on the sealing resin 81 to cover the input electrodes 31, the output electrodes 32 and the control electrodes 33 of the semiconductor elements 3. The first insulating layer 82 is made of a material containing a thermosetting synthetic resin and an additive that contains a metallic element that will form portions of the connecting conductors 83 (described later). The synthetic resin may be an epoxy resin or a polyimide resin, for example. The first insulating layer 82 is formed by compression molding.

Next, as shown in FIGS. 10-14, a plurality of connecting conductors 83 connecting to the input electrodes 31, output electrodes 32, control electrodes 33 of the semiconductor elements 3 or external terminals 6 are formed. The connecting conductors 83 correspond to the first connecting conductor 21, the second connecting conductor 22 and the connecting conductors 26, 27 of the semiconductor device A1. As shown in FIG. 14, each of the connecting conductors 83 has embedded parts 831 and a redistribution part 832. Each of the embedded parts 831 is embedded in the first insulating layer 82 and connected to one of the input electrodes 31, output electrodes 32, control electrodes 33 and external terminals 6. The redistribution part 832 is on the first insulating layer 82 and connected to the embedded part 831. As shown in FIG. 14, each of the embedded parts 831 and the redistribution parts 832 of the connecting conductors 83 has a base layer 83A and a plating layer 83B. The process of forming the connecting conductors 83 include a step of depositing a base layer 83A on the surface of the first insulating layer 82 and a step of forming a plating layer 83B that covers the base layer 83A.

First, as shown in FIG. 11, a base layer 83A is deposited on the surface of the first insulating layer 82. In this step, as shown in FIGS. 10 and 12, a plurality of holes 821 and a plurality of recesses 822 are formed in the first insulating layer 82 with a laser. The holes 821 penetrate the first insulating layer 82 in the z direction. The input electrodes 31, the output electrodes 32, the control electrodes 33 and the external terminals 6 are individually exposed through the holes 821. The holes 821 are formed by irradiating the first insulating layer 82 with a laser beam until the input electrodes 31, the output electrodes 32, the control electrodes 33 and the external terminals 6 are exposed while monitoring the positions of the input electrodes 31, the output electrodes 32, the control electrodes 33 and the external terminals 6 by image recognition using e.g. an infrared camera. The laser irradiation position is corrected based on the position information of the input electrodes 31, the output electrodes 32, the control electrodes 33 and the external terminals 6 obtained through image recognition. The recesses 822 are recessed from the surface of the first insulating layer 82 and connected to the holes 821. The recesses 822 are formed by irradiating the surface of the first insulating layer 82 with a laser beam. The laser beam may be an ultraviolet laser beam having a wavelength of 355 nm and a beam diameter of 17 μm, for example. As shown in FIG. 11, forming the holes 821 and the recesses 822 in the first insulating layer 82 results in deposition of the base layer 83A that covers the wall surfaces defining the holes 821 and the recesses 822. The base layer 83A is formed of a metallic element contained in the additive that is contained in first insulating layer 82. The metallic element contained in the additive is excited by laser irradiation. As a result, a metal layer containing the metallic element is deposited as the base layer 83A.

Next, as shown in FIG. 14, a plating layer 83B to cover the base layer 83A is formed. The plating layer 83B is made of a material containing copper. The plating layer 83B is formed by electroless plating. In this way, an embedded part 831 is formed in each of the holes 821, as shown in FIG. 13. Also, a redistribution part 832 is formed in each of the recesses 822. A plurality of connecting conductors 83 are formed in this way.

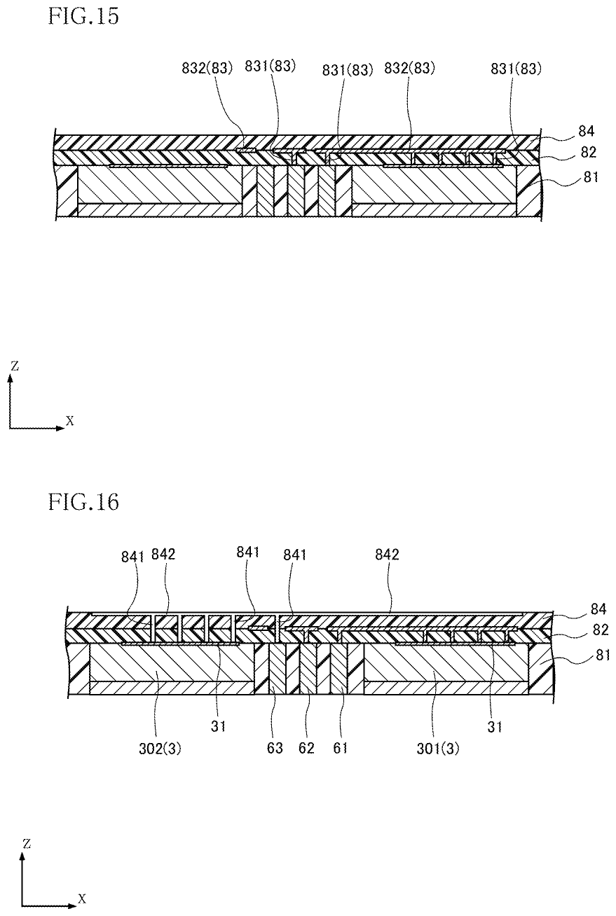

Next, as shown in FIG. 15, a second insulating layer 84 to cover the connecting conductors 83 is laminated on the first insulating layer 82. The second insulating layer 84 is made of the same material as the first insulating layer 82. The second insulating layer 84 is formed by compression molding.

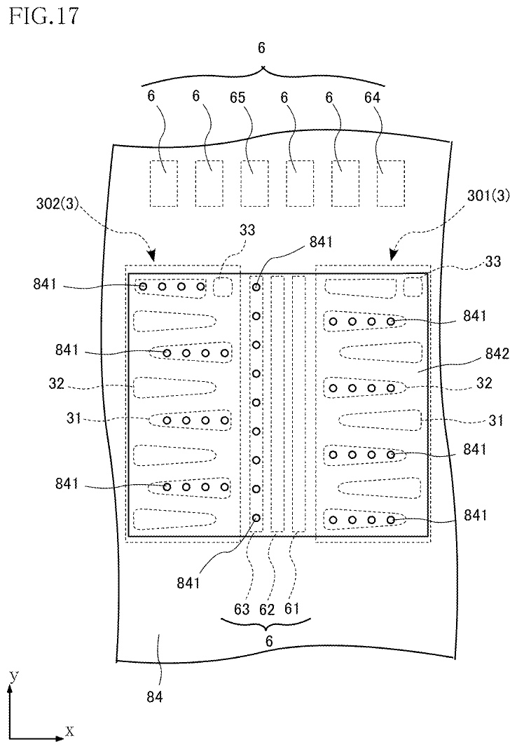

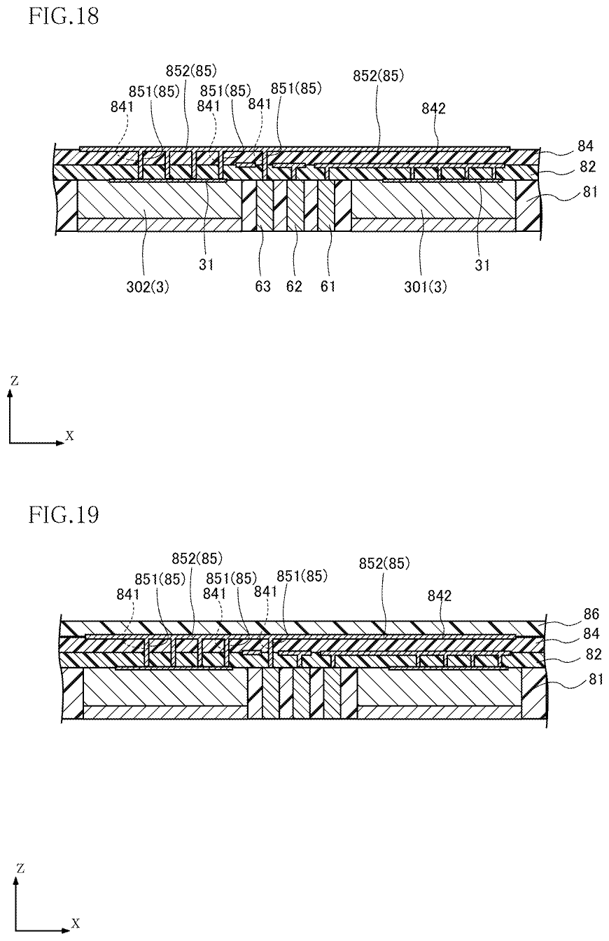

Next, as shown in FIGS. 16-18, a connecting conductor 85 connecting to the input electrodes 31 and the output electrodes 32 of the semiconductor elements 3 or the third external terminal 63 are formed. The connecting conductor 85 corresponds to the third connecting conductor 23 of the semiconductor device A1. As shown in FIG. 18, the connecting conductor 85 has embedded parts 851 and a redistribution part 852. Each embedded part 851 is entirely embedded through the first insulating layer 82 and the second insulating layer 84 and connected to one of the input electrodes 31, the output electrodes 32 and the third external terminal 63. The redistribution part 852 is on the second insulating layer 84 and connected to the embedded parts 851. As with the embedded parts 831 and the redistribution part 832, each of the embedded parts 851 and the redistribution part 852 of the connecting conductor 85 has a base layer and a plating layer. The process of forming the connecting conductor 85 includes a step of depositing a base layer on the surface of the second insulating layer 84 and a step of forming a plating layer that covers the base layer.

First, a base layer is deposited on the surface of the second insulating layer 84. In this step, as shown in FIGS. 16 and 17, a plurality of holes 841 and a recess 842 are formed in the second insulating layer 84 with a laser. The holes 841 penetrate the second insulating layer 84 in the z direction. The input electrodes 31, the output electrodes 32 and the third external terminal 63 are individually exposed through the holes 841. The holes 841 are formed by irradiating the second insulating layer 84 with a laser beam until the input electrodes 31, the output electrodes 32 and the third external terminal 63 are exposed while monitoring the positions of the input electrodes 31, the output electrodes 32 and the third external terminal 63 by image recognition using e.g. an infrared camera. The laser irradiation position is corrected based on the position information of the input electrodes 31, the output electrodes 32 and the third external terminal 63 obtained through image recognition. The recess 842 is recessed from the surface of the second insulating layer 84 and connected to the holes 841. The recess 842 is formed by irradiating the surface of the second insulating layer 84 with a laser beam. The laser beam may be an ultraviolet laser beam having a wavelength of 355 nm and a beam diameter of 17 μm, for example. Forming the holes 841 and the recess 842 in the second insulating layer 84 results in deposition of the base layer that covers the wall surfaces defining the holes 841 and the recess 842. The base layer is formed of a metallic element contained in the additive that is contained in second insulating layer 84. The metallic element contained in the additive is excited by laser irradiation. As a result, a metal layer containing the metallic element is deposited as the base layer.

Next, a plating layer to cover the base layer is formed. The plating layer is made of a material containing copper. The plating layer is formed by electroless plating. In this way, an embedded part 851 is formed in each of the holes 841, as shown in FIG. 18. Also, a redistribution part 852 is formed in the recess 842. A plurality of connecting conductors 85 are formed in this way.

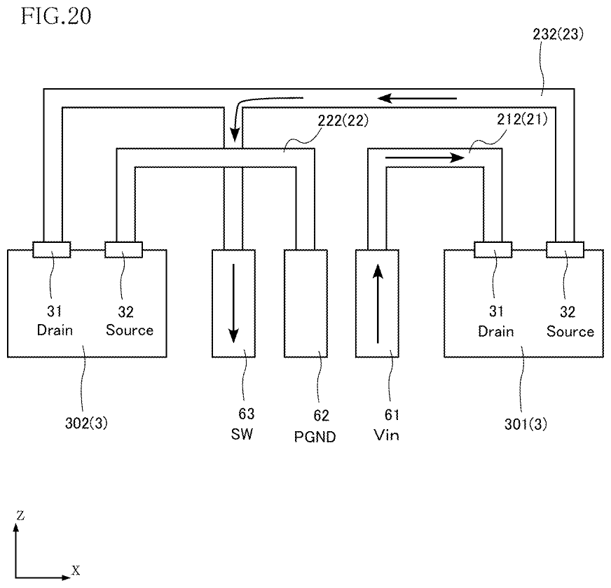

Next, as shown in FIG. 19, a third insulating layer 86 to cover the connecting conductor 85 is laminated on the second insulating layer 84. The third insulating layer 86 is made of the same material as the first insulating layer 82. The third insulating layer 86 is formed by compression molding.

Finally, the sealing resin 81, the first insulating layer 82, the second insulating layer 84 and the third insulating layer 86 are cut along predetermined cutting lines with e.g. a dicing blade for division into a plurality of individual pieces. The cutting is performed such that each of the individual pieces includes two semiconductor elements 3, and connecting conductors 83, 85 and external terminals 6 connected to the semiconductor elements. The sealing resin 81, the first insulating layer 82, the second insulating layer 84 and the third insulating layer 86 that are provided in each individual piece formed by this step correspond to the sealing resin 4, the first insulating layer 11, the second insulating layer 12 and the third insulating layer 13 of the semiconductor device A1. By going through the above-described steps, the semiconductor device A1 is obtained.

FIGS. 20-23 are schematic diagrams of the semiconductor device A1, showing the flow of current in the semiconductor device A1. FIG. 20 shows the current flow when the semiconductor element 301 is in the ON state and the semiconductor element 302 is in the OFF state. The current input from the first external terminal 61 flows through the first connecting conductor 21 and is input to the input electrodes 31 of the semiconductor element 301. The current then flows through the semiconductor element 301 from the input electrodes 31 to the output electrodes 32 and is output. The current output from the output electrodes 32 of the semiconductor element 301 flows through the third connecting conductor 23 and is output from the third external terminal 63.

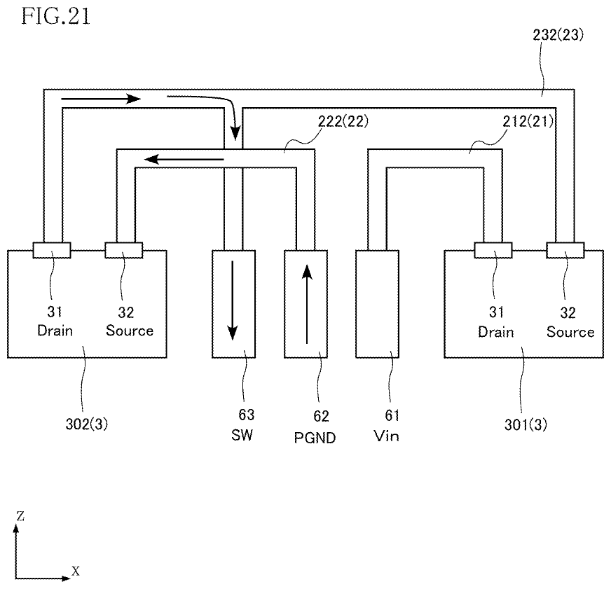

FIG. 21 shows the current flow when the semiconductor element 301 is switched from the state shown in FIG. 20 to the OFF state. Even when the semiconductor element 301 is switched to the OFF state, the output current from the third external terminal 63 continues due to the inductance of the load, and current is input from the load to the second external terminal 62. The current input from the second external terminal 62 flows through the second connecting conductor 22 and is input to the output electrodes 32 of the semiconductor element 302. The current then flows through a diode (not shown) connected in reverse parallel to the output electrodes 32 and the input electrodes 31, and is output from the input electrodes 31. The current output from the input electrodes 31 of the semiconductor element 302 flows through the third connecting conductor 23 and is output from the third external terminal 63. The current output from the third external terminal 63 gradually decreases.

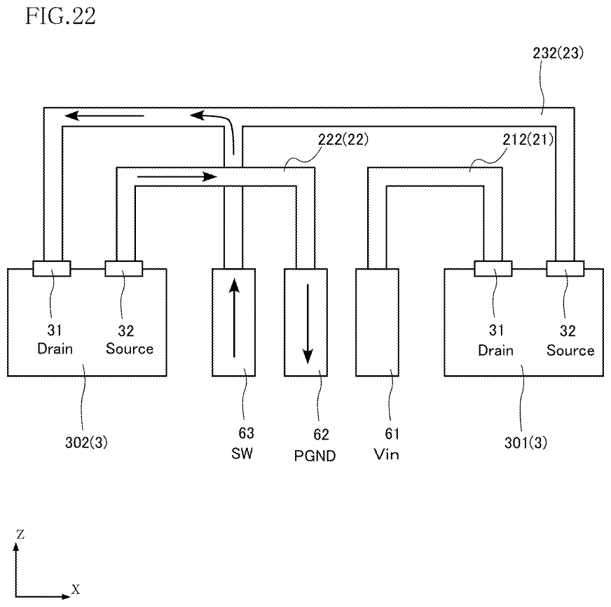

FIG. 22 shows the current flow after the semiconductor element 302 is switched from the state shown in FIG. 21 to the ON state at the timing when the current output from the third external terminal 63 becomes “0”. The current input from the third external terminal 63 flows through the third connecting conductor 23 and is input to the input electrodes 31 of the semiconductor element 302. The current then flows through the semiconductor element 302 from the input electrodes 31 to the output electrodes 32 and is output. The current output from the output electrodes 32 of the semiconductor element 302 flows through the second connecting conductor 22 and is output from the second external terminal 62.

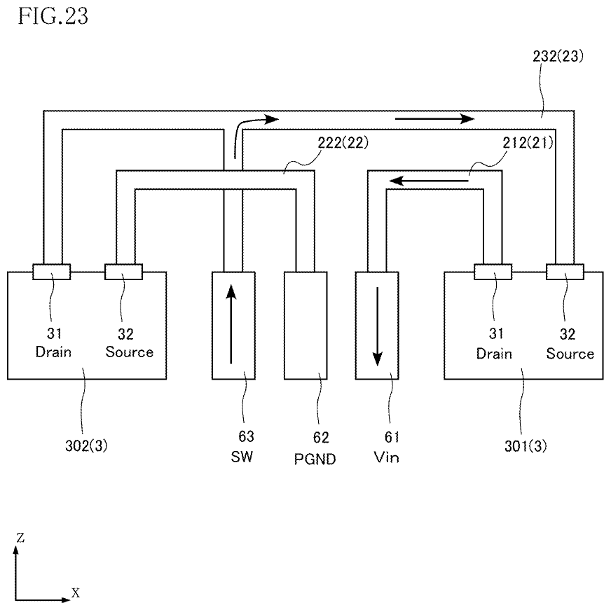

FIG. 23 shows the current flow when the semiconductor element 302 is switched from the state shown in FIG. 22 to the OFF state. Even when the semiconductor element 302 is switched to the OFF state, the input current to the third external terminal 63 continues due to the inductance of the load, and current is input from the load to the third external terminal 63. The current input from the third external terminal 63 flows through the third connecting conductor 23 and is input to the output electrodes 32 of the semiconductor element 301. The current then flows through a diode (not shown) connected in reverse parallel to the output electrodes 32 and the input electrodes 31, and is output from the input electrodes 31. The current output from the input electrodes 31 of the semiconductor element 301 flows through the first connecting conductor 21 and is output from the first external terminal 61. The current output from the first external terminal 61 gradually decreases. At the timing when the current input to the third external terminal 63 becomes “0”, the semiconductor element 301 is switched to the ON state to become the state shown in FIG. 20. By repeating the states shown in FIGS. 20-23, switching signals are output from the third external pin 63 to the load.

The advantages of the semiconductor device A1 are described below.

According to the present embodiment, the semiconductor device A1 has the first external terminal 61 electrically connected to the input electrodes 31 of the semiconductor element 301 via the first connecting conductor 21, and the second external terminal 62 electrically connected to the output electrodes 32 of the semiconductor element 302 via the second connecting conductor 22. The first external terminal 61 and the second external terminal 62 are disposed between the semiconductor element 301 and the semiconductor element 302 and exposed from the resin back surface 4b. When the semiconductor device A1 is mounted on a wiring board, the first external terminal 61 and the second external terminal 62 are bonded to the conductors of the wiring board. The first external terminal 61 functions as a Vin terminal, the second external terminal 62 functions as a PGND terminal, and a DC voltage is applied between the first external terminal 61 and the second external terminal 62 from the outside. Such an arrangement reduces the area (magnetic field generation area) of the loop of the current path from the first external terminal 61 to the second external terminal 62 via the first connecting conductor 21, the semiconductor element 301, the third connecting conductor 23, the semiconductor element 302 and the second connecting conductor 22. Thus, the inductance of the current path can be reduced. By reducing the inductance of the current path, the electric energy accumulated in the current path reduces, so that the surge voltage generated when the semiconductor element 301 or the semiconductor element 302 is switched to the ON state reduces.

According to the present embodiment, the first external terminal 61 and the second external terminal 62 are disposed adjacent to each other. As compared with the case in which the third external terminal 63 is disposed between the first external terminal 61 and the second external terminal 62, this arrangement further reduces the area (magnetic field generation area) of the loop of the current path from the first external terminal 61 to the second external terminal 62 via the first connecting conductor 21, the semiconductor element 301, the third connecting conductor 23, the semiconductor element 302 and the second connecting conductor 22. Thus, the inductance of the current path can be further reduced. Note that the third external terminal 63 may be disposed between the first external terminal 61 and the semiconductor element 301, rather than between the second external terminal 62 and the semiconductor element 302.

According to the present embodiment, when the semiconductor element 301 is in the ON state and the semiconductor element 302 is in the OFF state as shown in FIG. 20, current flows through the first external terminal 61 in the direction from the resin back surface 4b (the lower side in FIG. 20) toward the resin front surface 4a (the upper side in FIG. 20). On the other hand, in the third external terminal 63, current flows in the direction from the resin front surface 4a toward the resin back surface 4b. That is, the direction of the current flowing through the first external terminal 61 and the direction of the current flowing through the third external terminal 63 are opposite to each other in the z direction. Thus, the magnetic field generated by the current flowing through the first external terminal 61 and the magnetic field generated by the current flowing through the third external terminal 63 cancel each other out, which reduces the inductance generated. Similarly, when the semiconductor element 301 is switched to the OFF state as shown in FIG. 21, the direction of the current flowing through the second external terminal 62 and the direction of the current flowing through the third external terminal 63 become opposite to each other in the z direction. Thus, the magnetic field generated by the current flowing through the second external terminal 62 and the magnetic field generated by the current flowing through the third external terminal 63 cancel each other out, which reduces the inductance generated.

As shown in FIG. 22, when the semiconductor element 301 is in the OFF state and the semiconductor element 302 is in the ON state, the direction of the current flowing through the second external terminal 62 and the direction of the current flowing through the third external terminal 63 are opposite to each other in the z direction. Thus, the magnetic field generated by the current flowing through the second external terminal 62 and the magnetic field generated by the current flowing through the third external terminal 63 cancel each other out, which reduces the inductance generated. Similarly, when the semiconductor element 302 is switched to the OFF state as shown in FIG. 23, the direction of the current flowing through the first external terminal 61 and that flowing through the third external terminal 63 become opposite to each other in the z direction. Thus, the magnetic field generated by the current flowing through the first external terminal 61 and the magnetic field generated by the current flowing through the third external terminal 63 cancel each other out, which reduces the inductance generated.

According to the present embodiment, the first external terminal 61, the second external terminal 62 and the third external terminal 63 are each in the form of a plate having a thickness in the x direction and overlap with each other over a large area as viewed in the x direction. With such an arrangement, the currents flowing in the opposite direction from each other in the z direction provide a considerable inductance reduction effect.

According to the present embodiment, as shown in FIG. 20, the current input from the first external terminal 61 flows through the redistribution part 212 of the first connecting conductor 21 from the first external terminal 61 toward the semiconductor element 301. On the other hand, the current output from the semiconductor element 301 flows through the redistribution part 232 of the third connecting conductor 23 from the semiconductor element 301 toward the semiconductor element 302. That is, the direction of the current flowing through the redistribution part 212 and the direction of the current flowing through the redistribution part 232 are opposite to each other in the x direction. Thus, the magnetic field generated by the current flowing through the redistribution part 212 and the magnetic field generated by the current flowing through the redistribution part 232 cancel each other out, which reduces the inductance generated. In the state shown in FIG. 23 again, the direction of the current flowing through the redistribution part 212 and the direction of the current flowing through the redistribution part 232 are opposite to each other in the x direction, which reduces the inductance generated. Also, as shown in FIGS. 21 and 22, the direction of the current flowing through the redistribution part 222 and the direction of the current flowing through the redistribution part 232 are opposite to each other in the x direction. Thus, the magnetic field generated by the current flowing through the redistribution part 222 and the magnetic field generated by the current flowing through the redistribution part 232 cancel each other out, which reduces the inductance generated.

According to the present embodiment, the redistribution part 212 of the first connecting conductor 21 and the redistribution part 232 of the third connecting conductor 23 overlap with each other over a large area as viewed in the z direction. Similarly, the redistribution part 222 of the second connecting conductor 22 and the redistribution part 232 of the third connecting conductor 23 overlap with each other over a large area as viewed in the z direction. With such an arrangement, the currents flowing in the opposite direction from each other in the x direction provide a considerable inductance reduction effect.

According to the present embodiment, each semiconductor element 3 has a heat spreader 5 bonded to the element back surface 3b. The spreader back surfaces 5b of the heat spreaders 5 are exposed from the resin back surface 4b of the sealing resin 4. The semiconductor device A1 is mounted on a wiring board using the external terminals 6 exposed from the resin back surface 4b. At this time, the spreader back surfaces 5b, which are exposed from the resin back surface 4b, are also bonded to the wiring board using a bonding material such as solder. This allows the semiconductor device A1 to dissipate the heat generated by the semiconductor elements 3 to the wiring board through the heat spreaders 5. Thus, the semiconductor device A1 has higher heat dissipation as compared with a conventional semiconductor device in which the semiconductor elements 3 are covered with the insulating layer 1 and the sealing resin 4.

According to the present embodiment, a heat spreader 5 made of Cu is bonded to each semiconductor element 3. This prevents the semiconductor device A1 from warping due to thermal expansion.

According to the present embodiment, each connecting conductor 2 of the semiconductor device A1 is formed by irradiating the first insulating layer 82 or the second insulating layer 84, which is made of a material containing an additive that contains a metallic element, with a laser beam to deposit a base layer 83A and forming a plating layer 83B to cover the base layer 83A. The laser irradiation is performed while making corrections based on the position information of each electrode obtained by image recognition. Thus, even when the semiconductor elements 3 or external terminals 6 have been displaced due to shrinkage of the sealing resin 4 in curing, the connecting conductors 2 can be formed precisely in accordance with the actual positions of the electrodes and the external terminals 6. Thus, misalignment between the electrodes or external terminals 6 and the connecting conductors 2 at the joint portion is prevented.

Although an example in which the first insulating layer 11, the second insulating layer 12 and the third insulating layer 13 are made of the same material is described in the present embodiment, the present disclosure is not limited to this. For example, the third insulating layer 13 may not be made of a material containing an additive that contains a metallic element.

In the present embodiment, a manufacturing process has been described in which the first insulating layer 82, which is made of a material containing an additive that contains a metallic element, is irradiated with a laser beam to deposit a base layer 83A and then a plating layer 83B is formed to cover the base layer 83A, to thereby form the connecting conductors 83 (the first connecting conductor 21, the second connecting conductor 22 and connecting conductors 26 and 27). However, the present disclosure is not limited to such a manufacturing process, and the connecting conductors 83 may be formed by other methods. For example, a plurality of openings may be formed in the first insulating layer 82 by photolithography patterning using a mask so that the electrodes are exposed, and then connecting conductors 83 may be formed in the openings and on the first insulating layer 82 by plating. In this case, the first insulating layer 82 may not be made of a material containing an additive that contains a metallic element. Similarly, the connecting conductors 85 (the third connecting conductor 23) may be formed by other methods.

In the present embodiment, the first external terminal 61 and the second external terminal 62 are disposed adjacent to each other. However, the present disclosure is not limited to such an arrangement, and the third external terminal 63 may be disposed between the first external terminal 61 and the second external terminal 62.

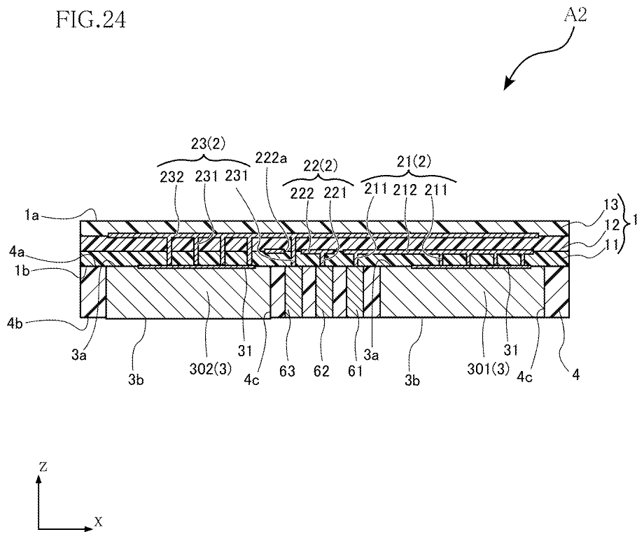

FIGS. 24-30 show other embodiments of the present disclosure. In these figures, the elements that are the same as or similar to those of the foregoing embodiment are denoted by the same reference signs as those used for the foregoing embodiment.

FIG. 24 is a view for explaining a semiconductor device A2 according to a second embodiment of the present disclosure. FIG. 24 is a sectional view of the semiconductor device A2 and corresponds to FIG. 5. The semiconductor device A2 of the present embodiment differs from the first embodiment in that the semiconductor device A2 is not provided with a heat spreader 5.

In the semiconductor device A2, which is not provided with a heat spreader 5, the element back surface 3b of each semiconductor element 3 is exposed through a resin opening 4c. In the present embodiment, the resin back surface 4b and the element back surfaces 3b are flush with each other. Only a portion of each element back surface 3b may be exposed from the resin back surface 4b, and another portion of each element back surface 3b may be covered with the sealing resin 4. In mounting the semiconductor device A2 on a wiring board, the element back surfaces 3b are bonded to the wiring board with a bonding material such as solder. This allows each semiconductor element 3 to dissipate the heat generated to the wiring board through the element back surface 3b.

According to the present embodiment, the element back surface 3b of each semiconductor element 3 is exposed from the resin back surface 4b of the sealing resin 4 and bonded to a wiring board when the semiconductor device A2 is mounted on the wiring board. This allows the semiconductor device A2 to dissipate the heat generated by the semiconductor elements 3 to the wiring board. Thus, the semiconductor device A2 has higher heat dissipation as compared with a conventional semiconductor device in which the semiconductor element 3 is covered with the insulating layer 1 and the sealing resin 4. In the semiconductor device A2, the first external terminal 61 and the second external terminal 62 are disposed between the semiconductor element 301 and the semiconductor element 302 and exposed from the resin back surface 4b, as with the first embodiment. With such an arrangement, the semiconductor device A2 can reduce the magnetic field generation area, which leads to a reduced inductance of the current path.

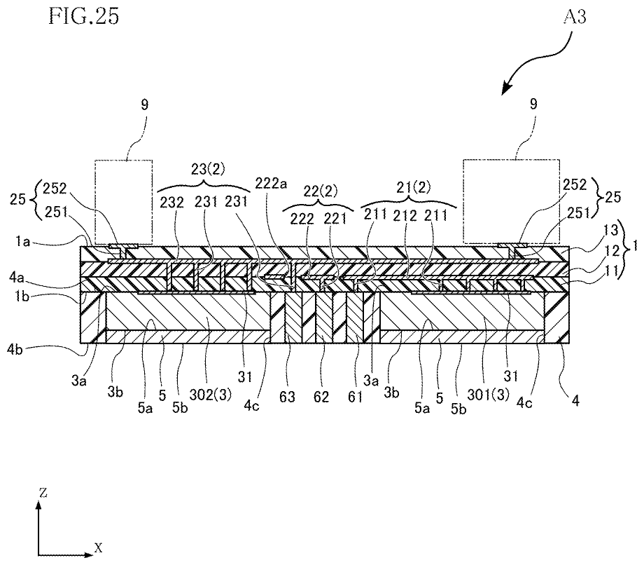

FIG. 25 is a view for explaining a semiconductor device A3 according to a third embodiment of the present disclosure. FIG. 25 is a sectional view of the semiconductor device A3 and corresponds to FIG. 5. The semiconductor device A3 of the present embodiment differs from the first embodiment in that the semiconductor device A3 is further provided with a plurality of front-surface connecting conductors 25 for mounting electronic components 9 on the insulating layer front surface 1a. Note that in FIG. 25 the electronic components 9 are indicated by imaginary lines (double-dotted lines). The same applies to the following figures.

The semiconductor device A3 is designed such that the electronic components 9 can be mounted on the insulating layer front surface 1a and is further provided with a plurality of front-surface connecting conductors 25. The electronic components 9 may be, for example, a resistor, a capacitor or a driver IC, but are not limited these. The number of the electronic components 9 to be mounted on the semiconductor device A3 and the arrangement of each electronic component are not limited.

The front-surface connecting conductors 25 are conductors that connect the electronic components 9 with, for example, the first connecting conductor 21, the second connecting conductor 22, the third connecting conductor 23, the connecting conductors 26, 27 or the external terminals 6, and form a conduction path. The front-surface connecting conductors 25 are disposed on the insulating layer 1. Each of the front-surface connecting conductors 25 has a configuration similar to e.g. the first connecting conductor. Each of the front-surface connecting conductors 25 has an embedded part 251 and a redistribution part 252. At least a portion of each embedded part 251 is embedded in the third insulating layer 13. The embedded part 251 of the front-surface connecting conductor 25 connected to the third connecting conductor 23 is entirely embedded in the third insulating layer 13. The embedded parts 251 of the front-surface connecting conductors 25 that are connected to the first connecting conductor 21, the second connecting conductor 22 or the connecting conductors 26 or 27 are embedded through the third insulating layer 13 and the second insulating layer 12. The embedded parts 251 of the front-surface connecting conductors 25 connected to the external terminals 6 are embedded through the third insulating layer 13, the second insulating layer 12 and the first insulating layer 11. The redistribution parts 252 are disposed on the side of the third insulating layer 13 that is opposite the second insulating layer 12, i.e., on the insulating layer front surface 1a. The redistribution parts 252 are connected to the embedded parts 251. The redistribution parts 252 function as a wiring to which the terminals of the electronic components 9 can be bonded.

As with the embedded parts 211 and the redistribution part 212, each of the embedded parts 251 and the redistribution parts 252 has a base layer 201 and a plating layer 202. The base layer 201 is formed of a metallic element contained in the additive that is contained in the insulating layer 13. The base layer 201 is in contact with the third insulating layer 13. The plating layer 202 is made of a material containing copper (Cu), for example, and in contact with the base layer 201. The base layer 201 of the embedded part 251 is in contact with the third insulating layer 13. The plating layer 202 of the embedded part 251 is surrounded by the base layer 201 of the embedded part 251. The base layer 201 of the redistribution part 252 is in contact with the third insulating layer 13. The plating layer 202 of the redistribution part 252 covers the base layer 201 of the redistribution part 252.

The semiconductor device A3 is manufactured by the same manufacturing process as the semiconductor device A1 until the step of forming the third insulating layer 86 (the third insulating layer 13). In the present embodiment, a plurality of holes and recesses are formed in the formed third insulating layer 86 by laser irradiation, and the base layers 201 of the front-surface connecting conductors 25 are deposited in the holes and recesses. Next, plating layers 202 to cover the base layer 201 are formed by electroless plating. Thus, the front-surface connecting conductors 25 are formed. The subsequent steps are the same as the semiconductor device A1.

In the semiconductor device A3 according to the present embodiment, the first external terminal 61 and the second external terminal 62 are disposed between the semiconductor element 301 and the semiconductor element 302 and exposed from the resin back surface 4b, as with the first embodiment. With such an arrangement, the semiconductor device A3 can reduce the magnetic field generation area, which leads to a reduced inductance of the current path. Moreover, since the semiconductor device A3 has front-surface connecting conductors 25 for functioning as a wiring on the insulating layer front surface 1a, electronic components 9 can be mounted on the insulating layer front surface 1a.

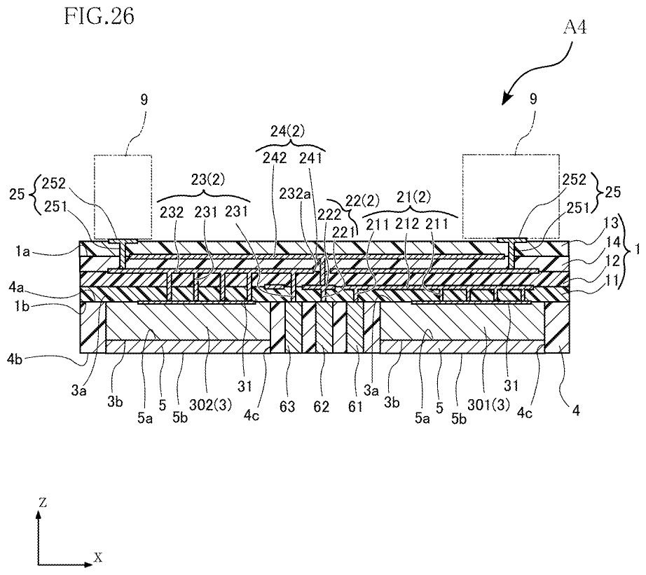

FIG. 26 is a view for explaining a semiconductor device A4 according to a fourth embodiment of the present disclosure. FIG. 26 is a sectional view of the semiconductor device A4 and corresponds to FIG. 5. The semiconductor device A4 of the present embodiment differs from the third embodiment in that the semiconductor device A4 is further provided with a fourth insulating layer 14 and a fourth connecting conductor 24.

In the semiconductor device A4, the insulating layer 1 further includes the fourth insulating layer 14, as shown in FIG. 26. As with the first insulating layer 11, the second insulating layer 12 and the third insulating layer 13, the fourth insulating layer 14 is made of a material containing a thermosetting synthetic resin and an additive that contains a metallic element forming portions of the connecting conductors 2. The fourth insulating layer 14 is laminated between the third insulating layer 13 and the second insulating layer 12. That is, the fourth insulating layer 14 is in contact with the third insulating layer 13 and the second insulating layer 12. The fourth insulating layer 14 is formed in the same manner as the second insulating layer 12 after the second insulating layer 12 and the third connecting conductor 23 are formed and before the third insulating layer 13 is formed.

The semiconductor device A4 is further provided with the fourth connecting conductor 24. The fourth connecting conductor 24 is a conductor connected to the second connecting conductor 22 and forms a conduction path. The fourth connecting conductor 24 is disposed on the fourth insulating layer 14. The fourth connecting conductor 24 has a configuration similar to the first connecting conductor 21 and has an embedded part 241 and a redistribution part 242. The embedded part 241 is embedded through the fourth insulating layer 14 and the second insulating layer 12 and connected to the second connecting conductor 22. The embedded part 241 is embedded through the third insulating layer 13, the second insulating layer 12 and the first insulating layer 11 and may be connected to the second external terminal 62. The redistribution part 242 is disposed between the third insulating layer 13 and the fourth insulating layer 14. The redistribution part 242 is connected to the embedded part 241.

As with the embedded parts 211 and the redistribution part 212, each of the embedded part 241 and the redistribution part 242 has a base layer 201 and a plating layer 202. The base layer 201 is formed of a metallic element contained in the additive that is contained in the fourth insulating layer 14 and the second insulating layer 12. The base layer 201 is in contact with the fourth insulating layer 14 and the second insulating layer 12. The plating layer 202 is made of a material containing copper (Cu), for example, and in contact with the base layer 201. The base layer 201 of the embedded part 241 is in contact with the fourth insulating layer 14 and the second insulating layer 12. The plating layer 202 of the embedded part 241 is surrounded by the base layer 201 of the embedded part 241. The base layer 201 of the redistribution part 242 is in contact with the fourth insulating layer 14. The plating layer 202 of the redistribution part 242 covers the base layer 201 of the redistribution part 242.

The semiconductor device A4 is manufactured by the same manufacturing process as the semiconductor device A3 according to the third embodiment until the step of forming the connecting conductor 85 (the third connecting conductor 23). In the present embodiment, the fourth insulating layer 14 is formed on the second insulating layer 84 (second insulating layer 12) to cover the connecting conductor 85 (the third connecting conductors 23). Next, a plurality of holes and recesses are formed in the formed fourth insulating layer 14 by laser irradiation, and the base layer 201 of the fourth connecting conductor 24 is deposited in the holes and recesses. Next, the plating layer 202 to cover the base layer 201 is formed by electroless plating. Thus, the fourth connecting conductor 24 is formed. The subsequent steps are the same as the semiconductor device A3.

In the semiconductor device A4 according to the present embodiment, the first external terminal 61 and the second external terminal 62 are disposed between the semiconductor element 301 and the semiconductor element 302 and exposed from the resin back surface 4b, as with the first embodiment. With such an arrangement, the semiconductor device A4 can reduce the magnetic field generation area, which leads to a reduced inductance of the current path. Moreover, the semiconductor device A4 is provided with the fourth insulating layer 14 laminated between the third insulating layer 13 and the second insulating layer 12, and the fourth connecting conductor 24 disposed on the fourth insulating layer 14 and connected to the second connecting conductor 22. The redistribution part 242 of the fourth connecting conductor 24 is disposed between the third insulating layer 13 and the fourth insulating layer 14 and located between the semiconductor elements 3 and the electronic components 9. The semiconductor device A4 having such a configuration reduces the influence of the high-frequency noise output from the semiconductor elements 3 on the electronic components 9.

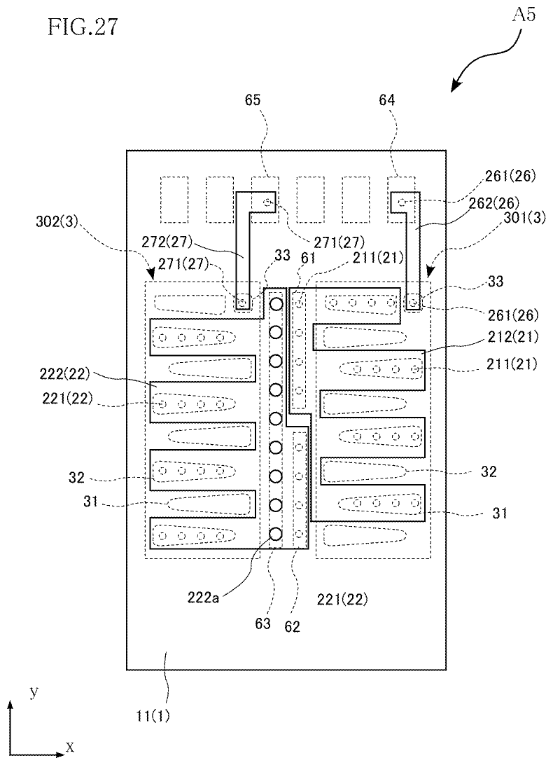

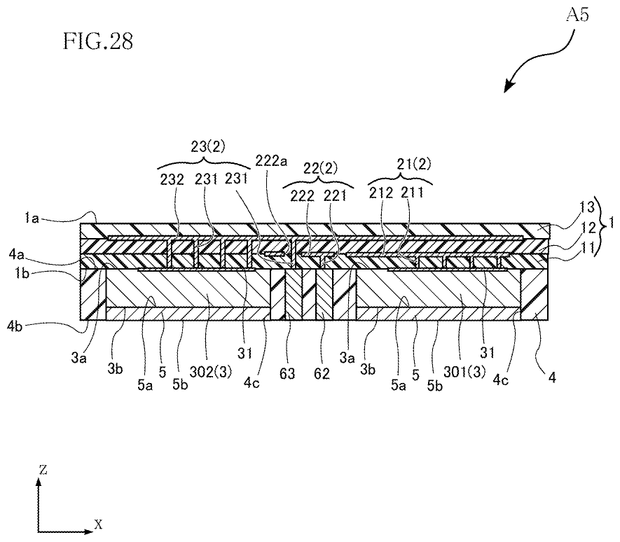

FIGS. 27 and 28 is a view for explaining a semiconductor device A5 according to a fifth embodiment of the present disclosure. FIG. 27 is a plan view of the semiconductor device A5 and corresponds to FIG. 2. FIG. 28 is a sectional view of the semiconductor device A5 and corresponds to FIG. 5. The semiconductor device A5 of the present embodiment differs from the first embodiment in that the first external terminal 61 and the second external terminal 62 are arranged side by side in the y direction, rather than in the x direction.

As shown in FIG. 27, in the semiconductor device A5, the first external terminal 61 and the second external terminal 62 each have a dimension in the y direction that is about half the dimension of the third external terminal 63 and are aligned in the y direction while being separated from the third external terminal 63 by the same distance. The redistribution part 212 has a shape that overlaps with the first external terminal 61 but does not overlap with the second external terminal 62 as viewed in the z direction. The redistribution part 222 has a shape that overlaps with the second external terminal 62 but does not overlap with the first external terminal 61 as viewed in the z direction.

In the semiconductor device A5 according to the present embodiment again, the first external terminal 61 and the second external terminal 62 are disposed between the semiconductor element 301 and the semiconductor element 302 and exposed from the resin back surface 4b. With such an arrangement, the semiconductor device A5 can reduce the magnetic field generation area, which leads to a reduced inductance of the current path. Moreover, since the first external terminal 61 and the second external terminal 62 are aligned in the y direction, the semiconductor device A5 can have a smaller dimension in the x direction than the semiconductor device A1.

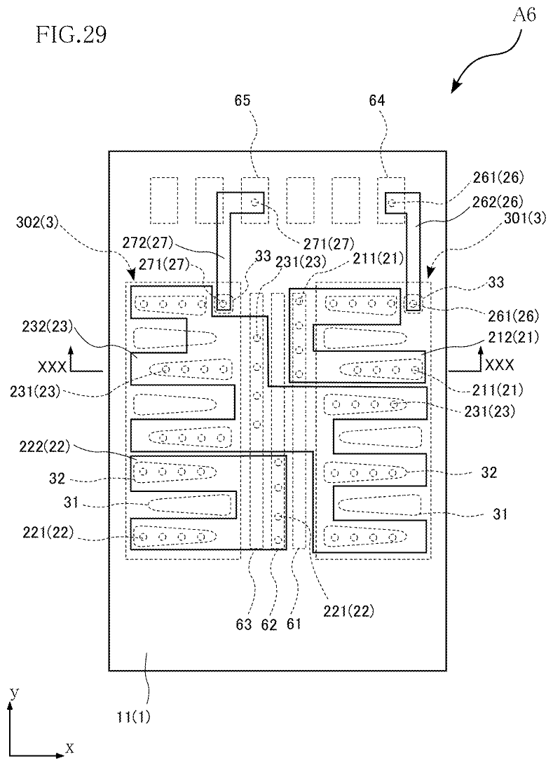

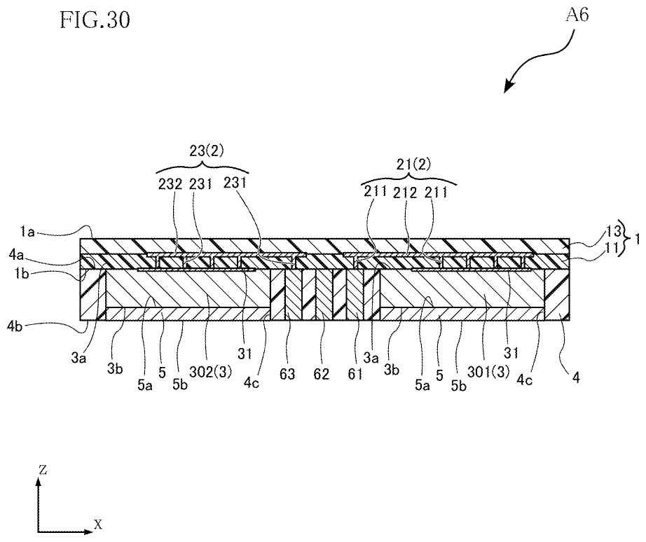

FIGS. 29 and 30 are views for explaining a semiconductor device A6 according to a sixth embodiment of the present disclosure. FIG. 29 is a plan view of the semiconductor device A6 and corresponds to FIG. 2. FIG. 30 is a sectional view of the semiconductor device A6 taken along line XXX-XXX in FIG. 29. The semiconductor device A6 of the present embodiment differs from the first embodiment in that the semiconductor device A6 does not include the second insulating layer 12 and that the third connecting conductor 23 is also disposed on the first insulating layer 11.

As shown in FIG. 30, the semiconductor device A6 does not include the second insulating layer 12, and the third insulating layer 13 is laminated on the first insulating layer 11. In the semiconductor device A6, the third connecting conductor 23 is formed on the first insulating layer 11, as with the first connecting conductor 21 and the second connecting conductor 22. As shown in FIG. 29, the redistribution part 232 is shaped such that it does not come into contact with the redistribution part 212 or the redistribution part 222 and overlaps with the input electrodes 31 of the semiconductor element 302 while overlapping with the output electrodes 32 of the semiconductor element 301.

In the semiconductor device A6 according to the present embodiment, the first external terminal 61 and the second external terminal 62 are disposed between the semiconductor element 301 and the semiconductor element 302 and exposed from the resin back surface 4b, as with the first embodiment. With such an arrangement, the semiconductor device A6 can reduce the magnetic field generation area, which leads to a reduced inductance of the current path. Further, since the semiconductor device A6 does not have the second insulating layer 12, its dimension in the z direction can be made smaller than that of the semiconductor device A1. Moreover, since the insulating layer 1 has a smaller number of layers, the manufacturing process can be simplified.

In the first through the sixth embodiments, the case in which the semiconductor elements 3 have electrodes only on the element front surfaces 3a has been described. However, the present disclosure is not limited to such a configuration, and the semiconductor element 3 may have back surface electrodes on the element back surfaces 3b. In such a case, in mounting the semiconductor device A1 or A3-A6 on a wiring board, the spreader back surfaces 5b of the heat spreaders 5 exposed through the resin openings 4c serve as external terminals that are bonded to the conductors of the wiring board with a conductive bonding material. In this case, the heat spreaders 5 needs to be electro-conductive. Also, in mounting the semiconductor device A2 on a wiring board, the element back surfaces 3b of the semiconductor elements 3 exposed through the resin openings 4c serve as external terminals that are bonded to the conductors of the wiring board with a conductive bonding material.

In the first through the sixth embodiments, the case in which each of the first external terminal 61, the second external terminal 62 and the third external terminal 63 is a plate-like member has been described. However, the present disclosure is not limited to this, and the shapes of the first external terminal 61, the second external terminal 62 and the third external terminal 63 may vary. The first external terminal 61, the second external terminal 62 and the third external terminal 63 may be via holes penetrating the sealing resin 4 in the z direction.

In the first through the sixth embodiments, the case in which the third external terminal 63 is disposed between the semiconductor element 301 and the semiconductor element 302 is described, but the present disclosure is not limited to this. The third external terminal 63 may be disposed at a position other than between the semiconductor element 301 and the semiconductor element 302. For example, the third external terminal 63 may be disposed on the opposite side of the first external terminal 61 with respect to the semiconductor element 301 in the x direction or on the opposite side of the second external terminal 62 with respect to the semiconductor element 302 in the x direction. As with the fourth external terminal 64 and the fifth external terminal 65, the third external terminal 63 may be arranged side by side with other external terminals 6 on one end (the upper end in FIG. 3) of the semiconductor device A1-A6 in the y direction.

The semiconductor device according to the present disclosure is not limited to the foregoing embodiments. The specific configuration of each part of the semiconductor device according to the present disclosure may be varied in design in many ways. The present disclosure includes the configurations described in the following clauses.

Clause 1.

A semiconductor device comprising:

a first semiconductor element and a second semiconductor element each having an element front surface and an element back surface facing away from each other in a thickness direction and a plurality of front surface electrodes disposed on the element front surface, the first semiconductor element and the second semiconductor element being arranged side by side in a first direction orthogonal to the thickness direction;

an insulating layer having an insulating layer back surface covering and facing each of the element front surfaces and an insulating layer front surface facing away from the insulating layer back surface in the thickness direction;

a sealing resin having a resin front surface in contact with the insulating layer back surface and a resin back surface facing away from the resin front surface in the thickness direction, the sealing resin covering a portion of each of the first semiconductor element and the second semiconductor element;

a first external terminal and a second external terminal disposed between the first semiconductor element and the second semiconductor element and each exposed from the resin back surface;

a first connecting conductor disposed on the insulating layer and electrically connecting at least one of the front surface electrodes of the first semiconductor element with the first external terminal; and

a second connecting conductor disposed on the insulating layer and electrically connecting at least one of the front surface electrodes of the second semiconductor element with the second external terminal.

Clause 2.

The semiconductor device according to clause 1, wherein the plurality of front surface electrodes of the first semiconductor element include a first input electrode and a first output electrode,

the plurality of front surface electrodes of the second semiconductor element include a second input electrode and a second output electrode,

the first connecting conductor connects to the first input electrode and the first external terminal, and

the second connecting conductor connects to the second output electrode and the second external terminal.

Clause 3.

The semiconductor device according to clause 2, further comprising a third connecting conductor disposed on the insulating layer and connecting to the first output electrode and the second input electrode.

Clause 4.

The semiconductor device according to clause 3, wherein the insulating layer includes a first insulating layer, a second insulating layer and a third insulating layer that are laminated,

the first insulating layer includes the insulating layer back surface, and

the third insulating layer includes the insulating layer front surface.

Clause 5.

The semiconductor device according to clause 4, wherein the first connecting conductor includes a first redistribution part disposed between the first insulating layer and the second insulating layer,

the second connecting conductor includes a second redistribution part disposed between the first insulating layer and the second insulating layer, and

the third connecting conductor includes a third redistribution part disposed between the second insulating layer and the third insulating layer.

Clause 6.

The semiconductor device according to clause 5, wherein at least a portion of the third redistribution part overlaps with the first redistribution part and the second redistribution part.

Clause 7.

The semiconductor device according to any one of clauses 4-6, further comprising a fourth connecting conductor disposed on the insulating layer and connecting to the third connecting conductor, wherein

the insulating layer further includes a fourth insulating layer laminated between the second insulating layer and the third insulating layer, and

the fourth connecting conductor includes a fourth redistribution part disposed between the fourth insulating layer and the third insulating layer.

Clause 8.

The semiconductor device according to any one of clauses 4-7, wherein the first insulating layer is made of a material containing a thermosetting synthetic resin and an additive that contains a metallic element forming a portion of the first connecting conductor.

Clause 9.

The semiconductor device according to clause 8, wherein the first connecting conductor has a base layer in contact with the first insulating layer and a plating layer in contact with the base layer, and

the base layer is formed of the metallic element contained in the additive.

Clause 10.

The semiconductor device according to any one of clauses 3-9, further comprising a third external terminal disposed between the first semiconductor element and the second semiconductor element and exposed from the resin back surface, the third external terminal connecting to the third connecting conductor.

Clause 11.

The semiconductor device according to clause 10, wherein the third external terminal is disposed between the first semiconductor element and the first external terminal or between the second semiconductor element and the second external terminal.

Clause 12.

The semiconductor device according to any one of clauses 3-9, further comprising a third external terminal disposed on an opposite side of the second semiconductor element with respect to the first semiconductor element or on an opposite side of the first semiconductor element with respect to the second semiconductor element in the first direction and exposed from the resin back surface, the third external terminal connecting to the third connecting conductor.

Clause 13.

The semiconductor device according to any one of clauses 2-12, wherein the first semiconductor element and the second semiconductor element are transistors each having an electron transit layer made of nitride semiconductor,

the first input electrode and the second input electrode are drain electrodes, and

the first output electrode and the second output electrode are source electrodes.

Clause 14.

The semiconductor device according to any one of clauses 1-13, wherein the first external terminal and the second external terminal are exposed from the resin front surface.

Clause 15.

The semiconductor device according to any one of clauses 1-14, further comprising a front-surface connecting conductor having a front surface redistribution part disposed on the insulating layer front surface.

Clause 16.

The semiconductor device according to any one of clauses 1-15, wherein the sealing resin has a resin opening formed in the resin back surface, the resin opening overlapping with the first semiconductor element as viewed in the thickness direction.

Clause 17.

The semiconductor device according to clause 16, wherein the element back surface of the first semiconductor element is exposed through the resin opening.

Clause 18.

The semiconductor device according to clause 16, further comprising a heat spreader bonded to a first element back surface that is the element back surface of the first semiconductor element,

wherein the heat spreader includes:

a spreader front surface facing the first element back surface; and

a spreader back surface facing away from the spreader front surface in the thickness direction,

the spreader back surfaces being exposed through the resin opening.

### LIST OF REFERENCE CHARACTERS

A1, A2, A3, A4, A5, A6: Semiconductor device
1: Insulating layer
11: First insulating layer
12: Second insulating layer
13: Third insulating layer
14: Fourth insulating layer
1a: Insulating layer front surface
1b: Insulating layer back surface
2: Connecting conductor
21: First connecting conductor
211: Embedded part
212: Redistribution part
22: Second connecting conductor
221: Embedded part
222: Redistribution part
222a: Through-hole
23: Third connecting conductor
231: Embedded part
232: Redistribution part
24: Fourth connecting conductor
241: Embedded part
242: Redistribution part
25: Front-surface connecting conductor
251: Embedded part
252: Redistribution part
26: Connecting conductor
261: Embedded part
262: Redistribution part
27: Connecting conductor
271: Embedded part
272: Redistribution part
201: Base layer
202: Plating layer
3: Semiconductor element
301: Semiconductor element
302: Semiconductor element
31: Input electrode
32: output electrode
33: Control electrode
3a: Element front surface
3b: Element back surface
4: Sealing resin
4a: Resin front surface
4b: Resin back surface
4c: Resin opening
5: Heat spreader
5a: Spreader front surface
5b: Spreader back surface
6: External terminal
61: First external terminal
62: Second external terminal
63: Third external terminal
64: Fourth external terminal
65: Fifth external terminal
9: Electronic component
81: Sealing resin
82: First insulating layer
821: Hole
822: Recess
83: Connecting conductor
83A: Base layer
83B: Plating layer
831: Embedded part
832: Redistribution part
84: Second insulating layer
841: Hole
842: Recess
85: Connecting conductor
851: Embedded part
852: Redistribution part
86: Third insulating layer

1. A semiconductor device comprising:
a first semiconductor element and a second semiconductor element each having an element front surface and an element back surface facing away from each other in a thickness direction and a plurality of front surface electrodes disposed on the element front surface, the first semiconductor element and the second semiconductor element being arranged side by side in a first direction orthogonal to the thickness direction;
an insulating layer having an insulating layer back surface covering and facing each of the element front surfaces and an insulating layer front surface facing away from the insulating layer back surface in the thickness direction;
a sealing resin having a resin front surface in contact with the insulating layer back surface and a resin back surface facing away from the resin front surface in the thickness direction, the sealing resin covering a portion of each of the first semiconductor element and the second semiconductor element;
a first external terminal and a second external terminal disposed between the first semiconductor element and the second semiconductor element and each exposed from the resin back surface;
a first connecting conductor disposed on the insulating layer and electrically connecting at least one of the front surface electrodes of the first semiconductor element with the first external terminal; and
a second connecting conductor disposed on the insulating layer and electrically connecting at least one of the front surface electrodes of the second semiconductor element with the second external terminal.

2. The semiconductor device according to claim 1, wherein the plurality of front surface electrodes of the first semiconductor element include a first input electrode and a first output electrode,
the plurality of front surface electrodes of the second semiconductor element include a second input electrode and a second output electrode,
the first connecting conductor connects to the first input electrode and the first external terminal, and
the second connecting conductor connects to the second output electrode and the second external terminal.

3. The semiconductor device according to claim 2, further comprising a third connecting conductor disposed on the insulating layer and connecting to the first output electrode and the second input electrode.

4. The semiconductor device according to claim 3, wherein the insulating layer includes a first insulating layer, a second insulating layer and a third insulating layer that are laminated,
the first insulating layer includes the insulating layer back surface, and
the third insulating layer includes the insulating layer front surface.

5. The semiconductor device according to claim 4, wherein the first connecting conductor includes a first redistribution part disposed between the first insulating layer and the second insulating layer,
the second connecting conductor includes a second redistribution part disposed between the first insulating layer and the second insulating layer, and
the third connecting conductor includes a third redistribution part disposed between the second insulating layer and the third insulating layer.

6. The semiconductor device according to claim 5, wherein at least a portion of the third redistribution part overlaps with the first redistribution part and the second redistribution part.

7. The semiconductor device according to claim 4, further comprising a fourth connecting conductor disposed on the insulating layer and connecting to the third connecting conductor, wherein
the insulating layer further includes a fourth insulating layer laminated between the second insulating layer and the third insulating layer, and
the fourth connecting conductor includes a fourth redistribution part disposed between the fourth insulating layer and the third insulating layer.

8. The semiconductor device according to claim 4, wherein the first insulating layer is made of a material containing a thermosetting synthetic resin and an additive that contains a metallic element forming a portion of the first connecting conductor.

9. The semiconductor device according to claim 8, wherein the first connecting conductor has a base layer in contact with the first insulating layer and a plating layer in contact with the base layer, and
the base layer is formed of the metallic element contained in the additive.

10. The semiconductor device according to claim 3, further comprising a third external terminal disposed between the first semiconductor element and the second semiconductor element and exposed from the resin back surface, the third external terminal connecting to the third connecting conductor.

11. The semiconductor device according to claim 10, wherein the third external terminal is disposed between the first semiconductor element and the first external terminal or between the second semiconductor element and the second external terminal.

12. The semiconductor device according to claim 3, further comprising a third external terminal disposed on an opposite side of the second semiconductor element with respect to the first semiconductor element or on an opposite side of the first semiconductor element with respect to the second semiconductor element in the first direction and exposed from the resin back surface, the third external terminal connecting to the third connecting conductor.

13. The semiconductor device according to claim 2, wherein the first semiconductor element and the second semiconductor element are transistors each having an electron transit layer made of nitride semiconductor,
the first input electrode and the second input electrode are drain electrodes, and
the first output electrode and the second output electrode are source electrodes.

14. The semiconductor device according to claim 1, wherein the first external terminal and the second external terminal are exposed from the resin front surface.

15. The semiconductor device according to claim 1, further comprising a front-surface connecting conductor having a front surface redistribution part disposed on the insulating layer front surface.

16. The semiconductor device according to claim 1, wherein the sealing resin has a resin opening formed in the resin back surface, the resin opening overlapping with the first semiconductor element as viewed in the thickness direction.

17. The semiconductor device according to claim 16, wherein the element back surface of the first semiconductor element is exposed through the resin opening.

18. The semiconductor device according to claim 16, further comprising a heat spreader bonded to a first element back surface that is the element back surface of the first semiconductor element,
wherein the heat spreader includes:
a spreader front surface facing the first element back surface; and
a spreader back surface facing away from the spreader front surface in the thickness direction,
the spreader back surfaces being exposed through the resin opening.
